(19) United States
(12) Patent Application Publication
(10) Pub. No.: US 2026/0096210 A1
(43) Pub. Date: Apr. 2, 2026

(54) INTEGRATED CIRCUIT, SYSTEM AND METHOD OF FORMING THE SAME

(71) Applicant: TAIWAN SEMICONDUCTOR MANUFACTURING COMPANY, LTD., Hsinchu (TW)

(72) Inventors: Yi-Yi CHEN, Hsinchu (TW); Chi-Yu LU, Hsinchu (TW); Chih-Liang CHEN, Hsinchu (TW); Chen-Ling WU, Hsinchu (TW); Ya-Chi CHOU, Hsinchu (TW)

(21) Appl. No.: 19/192,758

(22) Filed: Apr. 29, 2025

Related U.S. Application Data
(60) Provisional application No. 63/701,251, filed on Sep. 30, 2024.

(51) Int. Cl. H10D 84/90; H10D 89/10

(52) U.S. Cl. CPC H10D 84/988; H10D 89/10

(57) ABSTRACT

An integrated circuit includes a first and second active region, a first and second contact, a first conductor and a first insulating region. The first active region extends in a first direction, is on a first level above a front-side of a substrate, and corresponds to a first set of transistors. The second active region extends in the first direction, is on a second level, and corresponds to a second set of transistors. The first contact extends in a second direction, is on a third level, and overlaps the first active region. The second contact extends in the second direction, is on a fourth level, overlaps the second active region. The first conductor extends in the first direction, is on the third level and the fourth level, and is coupled to the first contact and the second contact. The first insulating region is within a recess of the first conductor.

### PRIORITY CLAIM

This application claims the benefit of U.S. Provisional Application No. 63/701,251, filed Sep. 30, 2024, which is incorporated herein by reference in its entirety.

### BACKGROUND

The semiconductor integrated circuit (IC) industry has produced a wide variety of digital devices to address issues in a number of different areas. Some of these digital devices, such as memory macros, are configured for the storage of data. As ICs have become smaller and more complex, the resistance of conductive lines within these digital devices is also changed affecting the operating voltages of these digital devices and overall IC performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a circuit diagram of an integrated circuit, in accordance with some embodiments.

FIG. 2 is a circuit diagram of an integrated circuit, in accordance with some embodiments.

FIGS. 3A-3D are corresponding diagrams of corresponding portions of a layout design of a corresponding integrated circuit, in accordance with some embodiments.

FIGS. 4A-4G are diagrams of an integrated circuit, in accordance with some embodiments.

FIGS. 5A-5H are diagrams of an integrated circuit, in accordance with some embodiments.

FIG. 6 is a diagram of an integrated circuit, in accordance with some embodiments.

FIGS. 7A-7B are corresponding diagrams of corresponding integrated circuits, in accordance with some embodiments.

FIG. 8 is a functional flow chart of a method of manufacturing an integrated circuit, in accordance with some embodiments.

FIG. 9 is a flow chart of a method of manufacturing an integrated circuit, in accordance with some embodiments.

FIG. 10 is a flowchart of a method of generating a layout design of an integrated circuit, in accordance with some embodiments.

FIG. 11 is a schematic view of a system for designing an IC layout design and manufacturing an IC circuit, in accordance with some embodiments.

FIG. 12 is a block diagram of an IC manufacturing system, and an IC manufacturing flow associated therewith, in accordance with at least one embodiment of the present disclosure.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, an integrated circuit includes a first active region. In some embodiments, the first active region extends in a first direction, is on a first level above a front-side of a substrate. In some embodiments, the first active region corresponds to a first set of transistors of a first dopant type.

In some embodiments, the integrated circuit further includes a second active region. In some embodiments, the second active region extends in the first direction. In some embodiments, the second active region is on a second level below the first level. In some embodiments, the second active region corresponds to a second set of transistors of a second dopant type different from the first dopant type.

In some embodiments, the integrated circuit further includes a first contact. In some embodiments, the first contact extends in a second direction different from the first direction. In some embodiments, the first contact is on a third level different from the first level and the second level. In some embodiments, the first contact overlaps the first active region.

In some embodiments, the integrated circuit further includes a second contact. In some embodiments, the second contact extends in the second direction. In some embodiments, the second contact is on a fourth level below the third level. In some embodiments, the second contact overlaps the second active region. In some embodiments, the second contact is separated from the first contact in the first direction and a third direction. In some embodiments, the third direction is different from the first direction and the second direction.

In some embodiments, the integrated circuit further includes a first conductor in a first region. In some embodiments, the first conductor extends in the first direction. In some embodiments, the first conductor is on the third level and the fourth level. In some embodiments, the first conductor is coupled to the first contact and the second contact.

In some embodiments, by including the first conductor in the first region of the integrated circuit, the first conductor, the first contact, and the second contact are usable to provide an electrical connection between one or more transistors of the first active region and one or more transistors of the second active region thereby resulting in additional routing resources of the integrated circuit compared to other approaches.

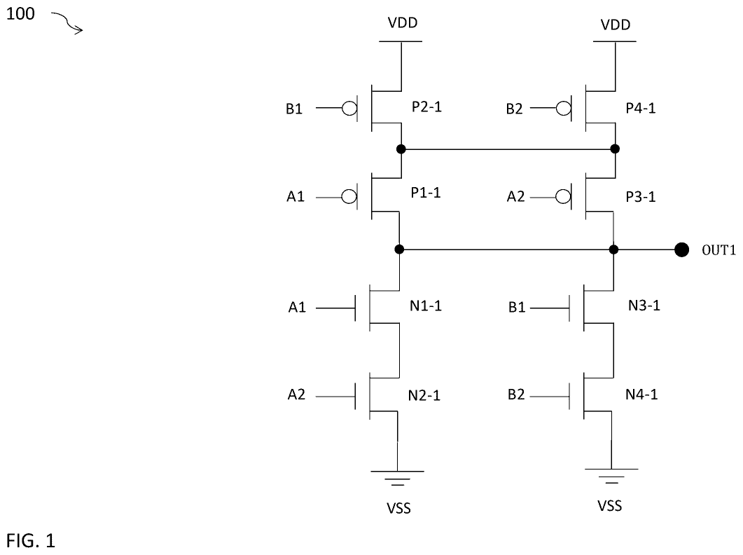

FIG. 1 is a circuit diagram of an integrated circuit 100, in accordance with some embodiments.

In some embodiments, integrated circuit 100 is a 2-2 AND OR INVERT (AOI) circuit. A 2-2 AOI circuit is used for illustration, other types of circuits including other types of AOI circuits are within the scope of the present disclosure.

Integrated circuit 100 includes P-type field effect transistors (PFET) transistors P1-1, P2-1, P3-1 and P4-1 and NFET transistors N1-1, N2-1, N3-1 and N4-1.

A gate terminal of PFET transistor P1-1 is configured as an input node (not labelled) configured to receive an input signal A1. A gate terminal of NFET transistor N1-1 is configured as an input node (not labelled) configured to receive input signal A1. In some embodiments, the gate terminal of PFET transistor P1-1 is coupled to the gate terminal of NFET transistor N1-1.

A gate terminal of PFET transistor P2-1 is configured as an input node (not labelled) configured to receive an input signal B1. A gate terminal of NFET transistor N3-1 is configured as an input node (not labelled) configured to receive input signal B1. In some embodiments, the gate terminal of PFET transistor P2-1 is coupled to the gate terminal of NFET transistor N3-1.

A gate terminal of PFET transistor P3-1 is configured as an input node (not labelled) configured to receive an input signal A2. A gate terminal of NFET transistor N2-1 is configured as an input node (not labelled) configured to receive input signal A2. In some embodiments, the gate terminal of PFET transistor P3-1 is coupled to the gate terminal of NFET transistor N2-1.

A gate terminal of PFET transistor P4-1 is configured as an input node (not labelled) configured to receive an input signal B2. A gate terminal of NFET transistor N4-1 is configured as an input node (not labelled) configured to receive input signal B2. In some embodiments, the gate terminal of PFET transistor P4-1 is coupled to the gate terminal of NFET transistor N4-1. In some embodiments, at least input signal A1, A2, B1 or B2 is a logically low signal or a logically high signal.

A source terminal of PFET transistor P2-1 and a source terminal of PFET transistor P4-1 are coupled to the voltage supply VDD. In some embodiments, the source terminal of PFET transistor P2-1 and the source terminal of PFET transistor P4-1 are coupled together.

Each of a drain terminal of PFET transistor P2-1, a source terminal of PFET transistor P1-1, a drain terminal of PFET transistor P4-1, and a source terminal of PFET transistor P3-1 are coupled together.

Each of a drain terminal of PFET transistor P1-1, a drain terminal of PFET transistor P3-1, a drain terminal of NFET transistor N1-1 and a drain terminal of NFET transistor N3-1 are coupled together, and are configured as an output node OUT1.

A source terminal of NFET transistor N1-1 and a drain terminal of NFET transistor N2-1 are coupled together. A source terminal of NFET transistor N3-1 and a drain terminal of NFET transistor N4-1 are coupled together.

A source terminal of NFET transistor N2-1 and a source terminal of NFET transistor N4-1 are each coupled to a reference voltage supply VSS. In some embodiments, the source terminal of NFET transistor N2-1 and the source terminal of NFET transistor N4-1 are coupled together.

Other circuits, other types of transistors, and/or quantities of transistors are within the scope of various embodiments. For example, in some embodiments, integrated circuit 100 includes other types of AOI logic circuits, such as a 2-1 AOI logic circuit. Other values of at least input signal A1, A2, B1 or B2 are within the scope of various embodiments.

Other configurations of integrated circuit 100 are within the scope of the present disclosure.

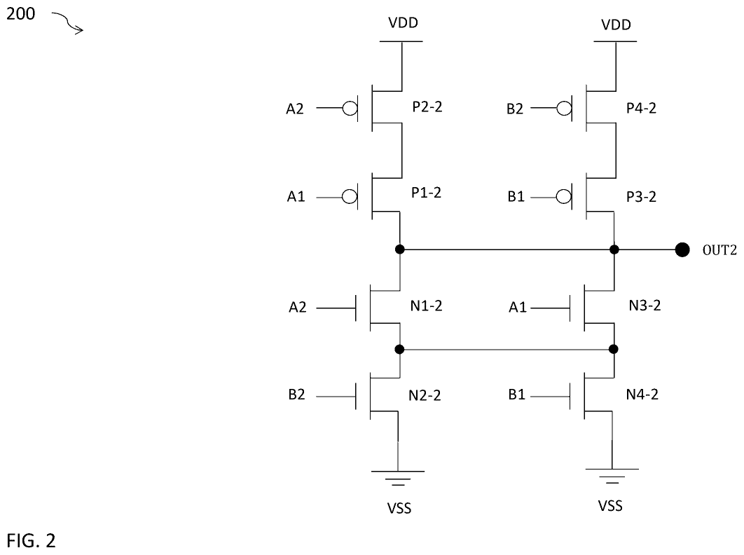

FIG. 2 is a circuit diagram of an integrated circuit 200, in accordance with some embodiments.

In some embodiments, integrated circuit 200 is a 2-2 OR AND INVERT (OAI) circuit. A 2-2 OAI circuit is used for illustration, other types of circuits including other types of OAI circuits are within the scope of the present disclosure.

Integrated circuit 200 includes PFET transistors P1-2, P2-2, P3-2 and P4-2 and NFET transistors N1-2, N2-2, N3-2 and N4-2.

A gate terminal of PFET transistor P1-2 is configured as an input node (not labelled) configured to receive an input signal A1. A gate terminal of NFET transistor N3-2 is configured as an input node (not labelled) configured to receive input signal A1. In some embodiments, the gate terminal of PFET transistor P1-2 is coupled to the gate terminal of NFET transistor N3-2.

A gate terminal of PFET transistor P2-2 is configured as an input node (not labelled) configured to receive an input signal A2. A gate terminal of NFET transistor N1-2 is configured as an input node (not labelled) configured to receive input signal A2. In some embodiments, the gate terminal of PFET transistor P2-2 is coupled to the gate terminal of NFET transistor N1-2.

A gate terminal of PFET transistor P3-2 is configured as an input node (not labelled) configured to receive an input signal B1. A gate terminal of NFET transistor N4-2 is configured as an input node (not labelled) configured to receive input signal B1. In some embodiments, the gate terminal of PFET transistor P3-2 is coupled to the gate terminal of NFET transistor N4-2.

A gate terminal of PFET transistor P4-2 is configured as an input node (not labelled) configured to receive an input signal B2. A gate terminal of NFET transistor N2-2 is configured as an input node (not labelled) configured to receive input signal B2. In some embodiments, the gate terminal of PFET transistor P4-2 is coupled to the gate terminal of NFET transistor N2-2. In some embodiments, at least input signal A1, A2, B1 or B2 is a logically low signal or a logically high signal.

A source terminal of PFET transistor P2-2 and a source terminal of PFET transistor P4-2 are coupled to the voltage supply VDD. In some embodiments, the source terminal of PFET transistor P2-2 and the source terminal of PFET transistor P4-2 are coupled together.

A drain terminal of PFET transistor P2-2 and a source terminal of PFET transistor P1-2 are coupled together.

A drain terminal of PFET transistor P4-2 and a source terminal of PFET transistor P3-2 are coupled together.

Each of a drain terminal of PFET transistor P1-2, a drain terminal of PFET transistor P3-2, a drain terminal of NFET transistor N1-2 and a drain terminal of NFET transistor N3-2 are coupled together, and are configured as an output node OUT2.

Each of a source terminal of NFET transistor N1-2, a drain terminal of NFET transistor N2-2, a source terminal of NFET transistor N3-2 and a drain terminal of NFET transistor N4-2 are coupled together.

A source terminal of NFET transistor N2-2 and a source terminal of NFET transistor N4-2 are each coupled to a reference voltage supply VSS. In some embodiments, the source terminal of NFET transistor N2-2 and the source terminal of NFET transistor N4-2 are coupled together.

Other circuits, other types of transistors, and/or quantities of transistors are within the scope of various embodiments. For example, in some embodiments, integrated circuit 200 includes other types of OAI logic circuits, such as a 2-1 OAI logic circuit. Other values of at least input signal A1, A2, B1 or B2 are within the scope of various embodiments.

Other configurations of integrated circuit 200 are within the scope of the present disclosure.

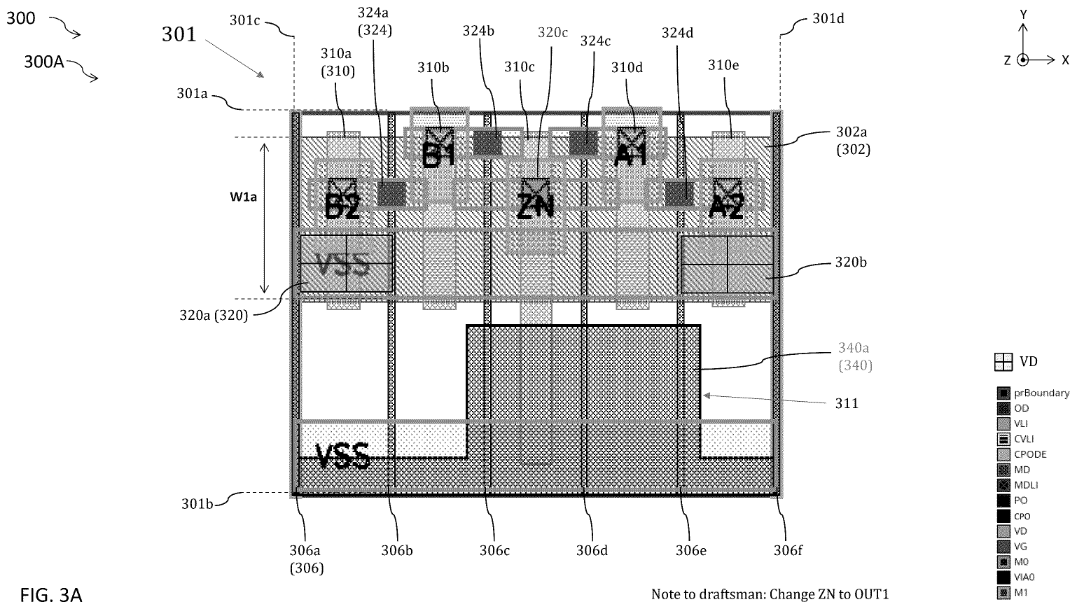

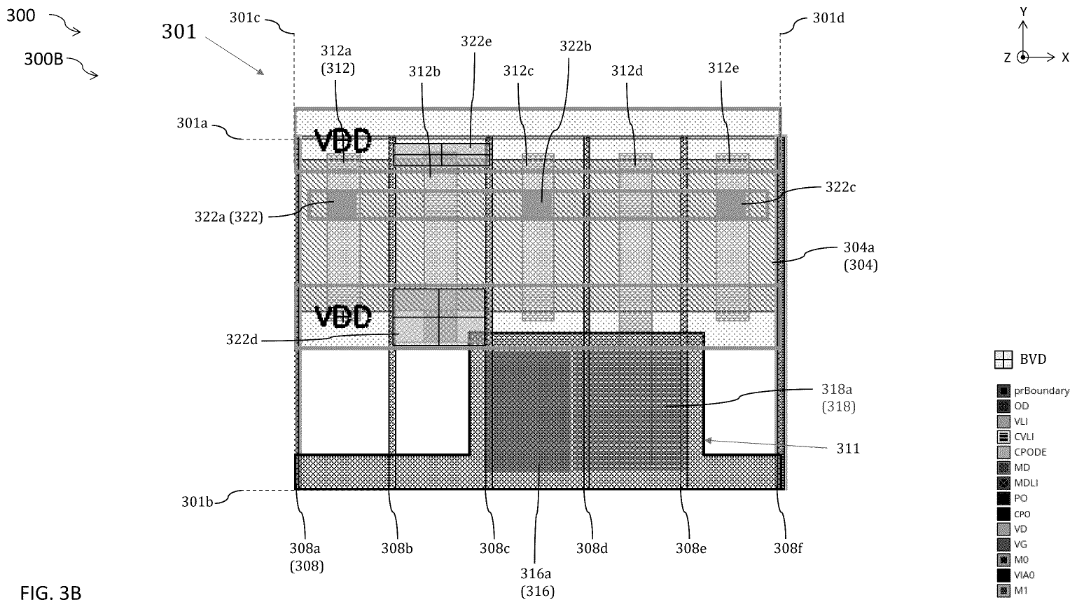

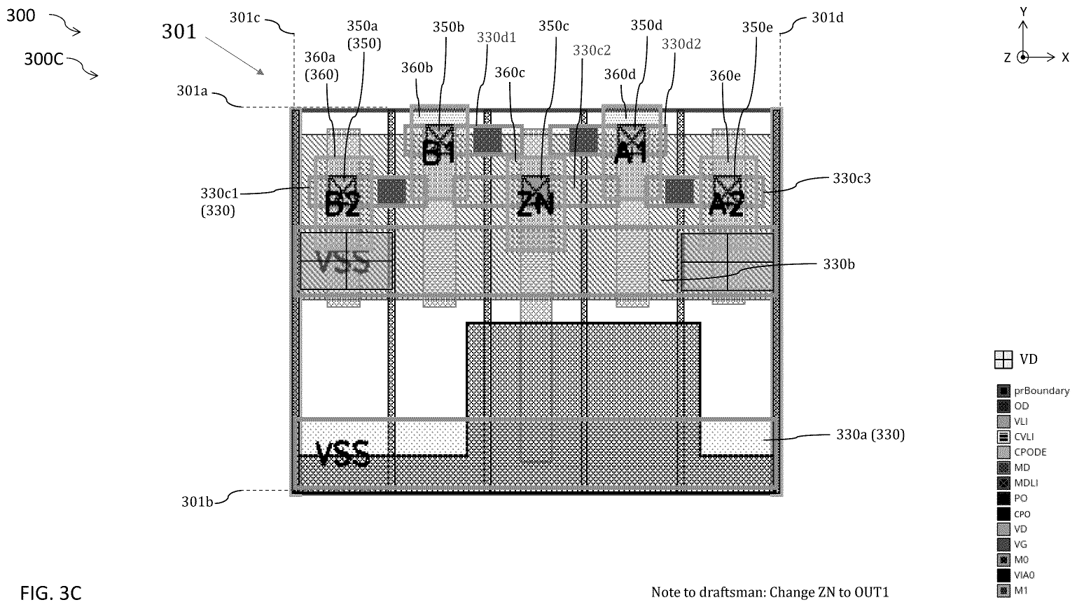

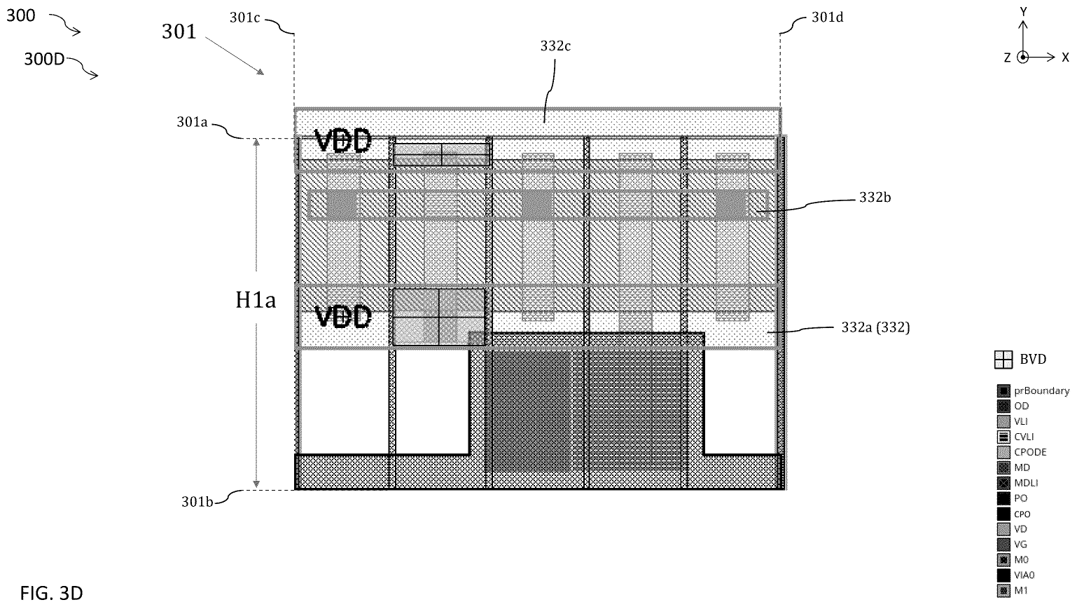

FIGS. 3A-3D are corresponding diagrams of corresponding portions 300A-300D of a layout design 300 of a corresponding integrated circuit, in accordance with some embodiments.

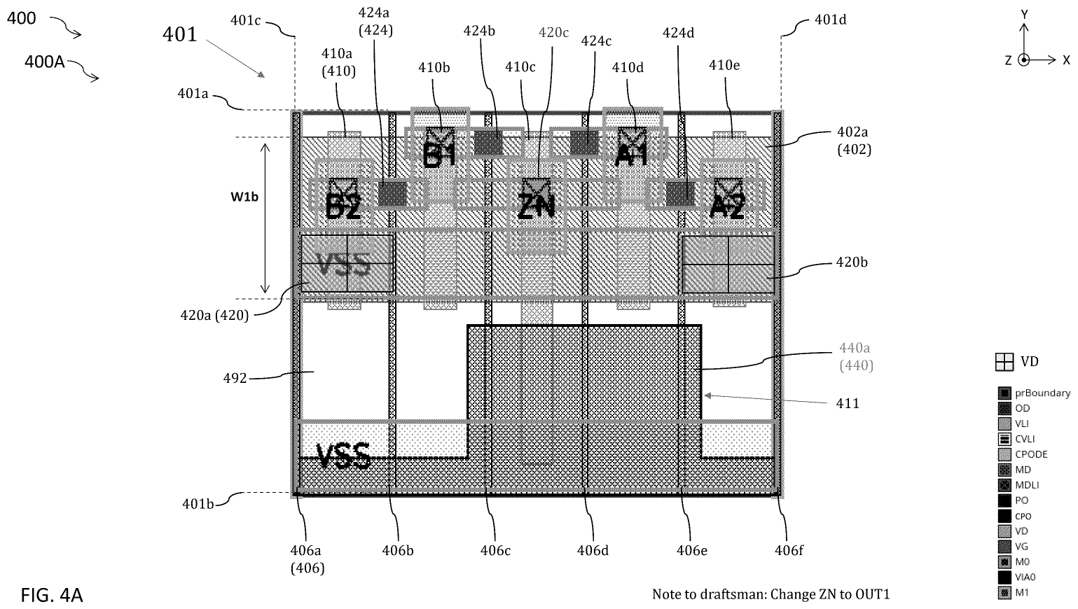

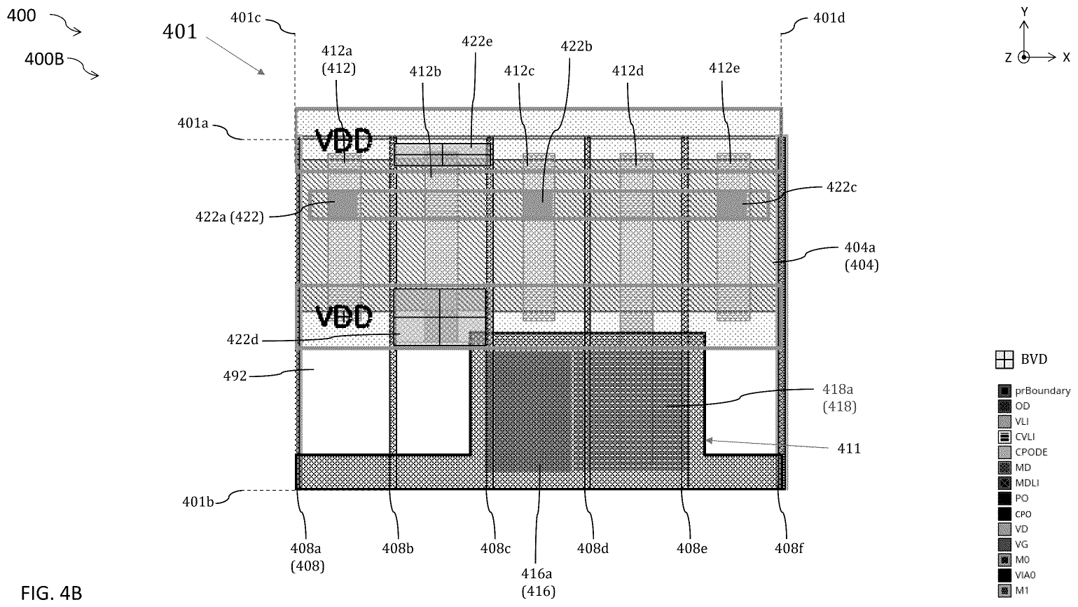

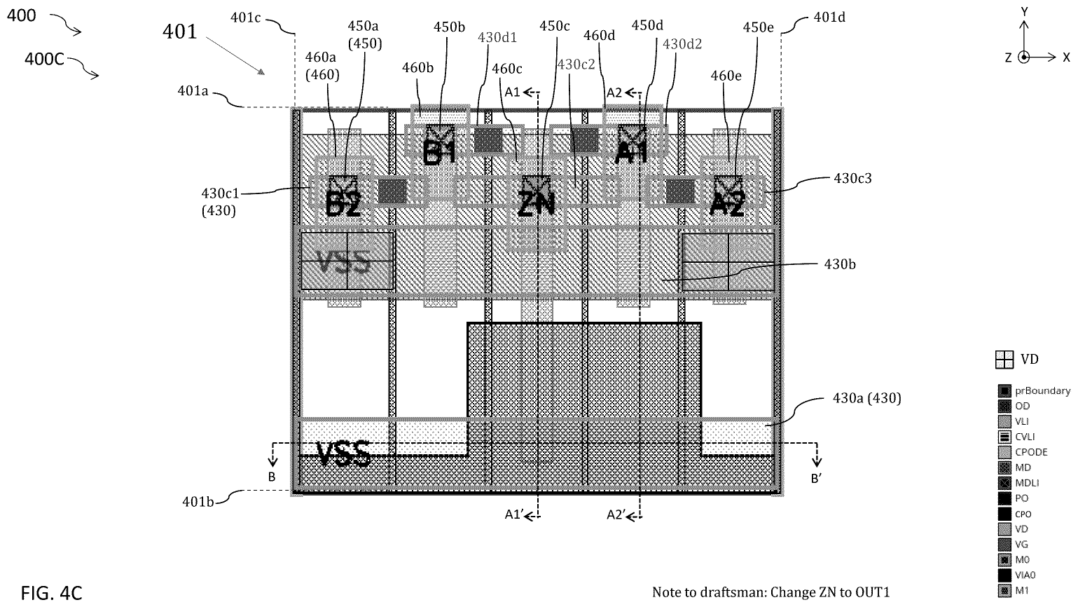

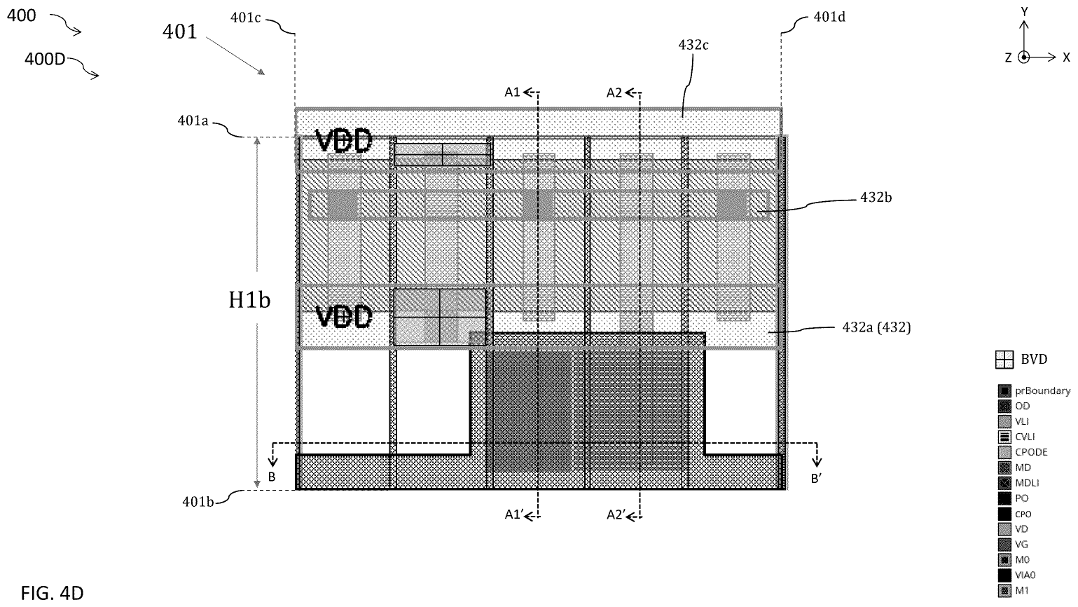

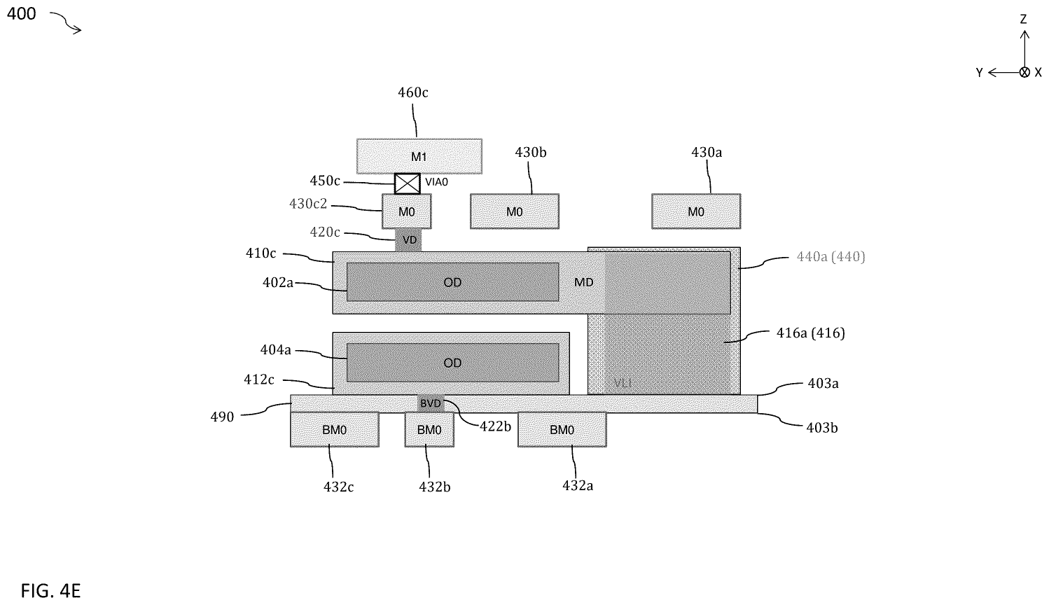

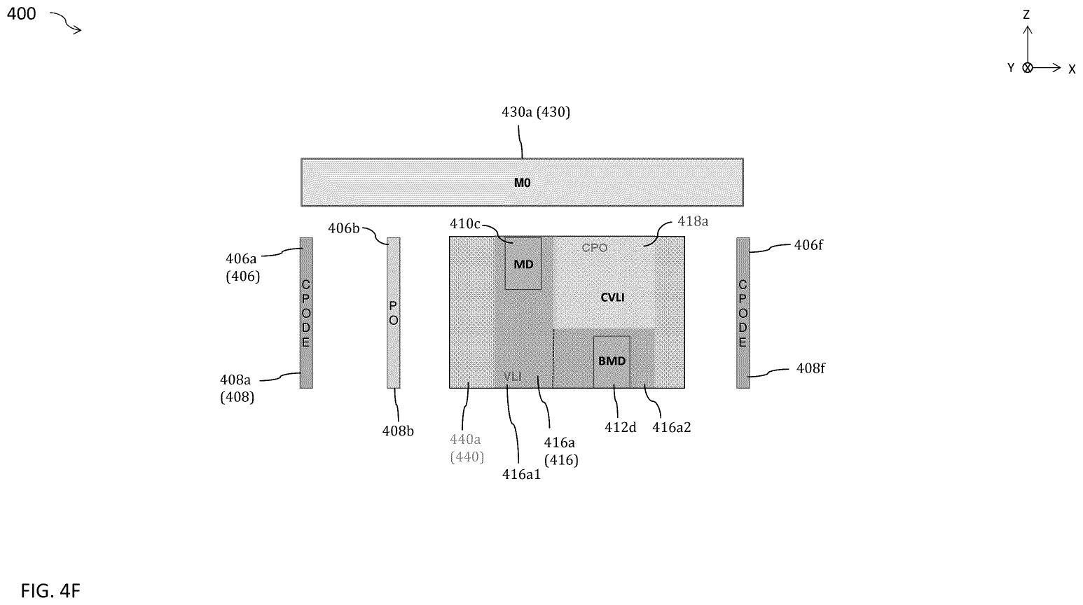

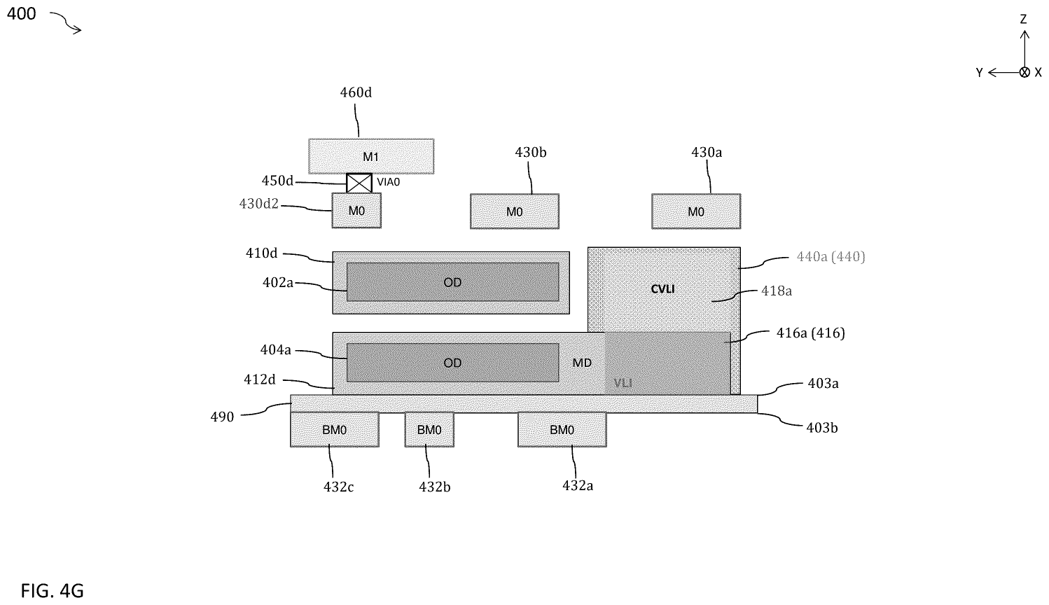

Layout design 300 is a layout of an integrated circuit 400 of FIGS. 4A-4G or integrated circuit 100. Layout design 300 is a layout of integrated circuit 100 of FIG. 1.

Portion 300A includes one or more features of layout design 300 of an active level or an oxide diffusion (OD) level, a gate (POLY) level, a cut poly (CPO) level, a metal over diffusion (MD) level, a metal 0 (M0) level, a via over gate (VG) level, a via over diffusion (VD) level, a metal 1 (M1) level and a via over metal 0 (V0) level.

Portion 300B includes one or more features of layout design 300 of the OD level, the POLY level, the CPO level, a backside metal over diffusion (BMD) level, a via local interconnect (VLI), a CVLI level, a backside metal 0 (BM0) and a backside via over diffusion (BVD) level, Portion 300C includes one or more features of layout design 300 of the OD level, the POLY level, the CPO level, the MD level, the M0 level, the VG level, the VD level, the M1 level and the V0 level. In some embodiments, portion 300C is portion 300A, but the labels in portions 300C and 300A are different from each other for ease of illustration.

Portion 300D include one or more features of layout design 300 of the OD level, the POLY level, the CPO level, the BMD level, the VLI level, the CVLI level, the BM0 level and the BVD level. In some embodiments, portion 300D is portion 300B, but the labels in portions 300D and 300B are different from each other for ease of illustration.

FIGS. 3A-3D are corresponding diagrams of corresponding portions 300A-300D of layout design 300, simplified for ease of illustration.

For ease of illustration, some of the labeled elements of one or more of FIGS. 1-8B are not labelled in one or more of FIGS. 1-8B. In some embodiments, layout design 300 includes additional elements not shown in FIGS. 3A-3D.

Layout design 300 includes one or more features of the OD level, the POLY level, the CPO level, the MD level, the M0 level, the VG level, the VD level, the M1 level and the V0 level, the BMD level, the VLI level, the CVLI level, the BM0 level and the BVD level. In some embodiments, at least layout design 300, or integrated circuit 400, 500, 600, 700A or 700B includes additional elements not shown in FIGS. 3A-3D, 4A-4G, 5A-5H, 6, 7A and 7B.

Layout design 300 is usable to manufacture integrated circuit 400 of FIGS. 4A-4G.

Portion 300A is a layout of portion 400A of integrated circuit 400 of FIG. 4A, portion 300B is a layout of portion 400B of integrated circuit 400 of FIG. 4B, portion 300C is a layout of portion 400C of integrated circuit 400 of FIG. 4C, and portion 300D is a layout of portion 400D of integrated circuit 400 of FIG. 4D, and similar detailed description is omitted for brevity.

Layout design 300 includes a cell 301. The cell 301 has cell boundaries 301a and 301b that extend in a first direction X, and cell boundaries 301c and 301d that extend in a second direction Y. In some embodiments, at least one of the first direction X, the second direction Y or a third direction Z is different from another of the first direction X, the second direction Y or the third direction Z. In some embodiments, layout design 300 abuts other cell layout designs (not shown) along cell boundaries 301c and 301d. In some embodiments, layout design 300 abuts other cell layout designs (not shown) along cell boundaries 301a and 301b that extend in the first direction X. In some embodiments, layout design 300 is a double height standard cell with a height H1a in the second direction Y. In some embodiments, cell 301 is useable to manufacture a cell 401.

In some embodiments, cell 301 is a standard cell, and layout design 300 corresponds to a layout of a standard cell defined by cell boundaries 301a, 301b, 301c and 301d. In some embodiments, a cell 301 is a predefined portion of layout design 300 including one or more transistors and electrical connections configured to perform one or more circuit functions. In some embodiments, cell 301 is bounded by cell boundaries 301a, 301b, 301c and 301d, and thus corresponds to a region of functional circuit components or devices that are part of a standard cell. In some embodiments, layout design 300 is a layout design of an integrated circuit, such as integrated circuit 100 of FIG. 1.

Layout design 300 includes one or more active region layout patterns 302a (collectively referred to as a “set of active region patterns 302”) or one or more active region layout patterns 304a (collectively referred to as a “set of active region patterns 304”) extending in the first direction X.

Embodiments of the present disclosure use the term “layout pattern” which is hereinafter also referred to as “patterns” in the remainder of the present disclosure for brevity.

The set of active region patterns 302 is above the set of active region patterns 304.

Active region pattern 302a of the set of active region patterns 302 are separated from one another in the second direction Y. Active region pattern 304a of the set of active region patterns 304 are separated from one another in the second direction Y.

Active region patterns 302a and 304a are separated from one another in a third direction Z.

The set of active region patterns 302 is usable to manufacture a corresponding set of active regions 402 of integrated circuit 100, 200, 400, 500, 600, 700A or 700B. The set of active region patterns 304 is usable to manufacture a corresponding set of active regions 404 of integrated circuit 100, 200, 400, 500, 600, 700A or 700B.

In some embodiments, at least one of the set of active regions 402 or 404 are located on the front-side 403a of integrated circuit 100, 200, 400, 500, 600, 700A or 700B. In some embodiments, at least one of the set of active regions 402 or 404 corresponds to source and drain regions of one or more complementary FET (CFET) transistors. In some embodiments, at least one of the set of active regions 402 or 404 correspond to source and drain regions of one or more nanosheet transistors or nanowire transistors. Other transistor types are within the scope of the present disclosure. In some embodiments, at least one of the set of active regions 402 or 404 corresponds to source and drain regions of one or more finFET transistors.

In some embodiments, active region pattern 302a is usable to manufacture corresponding active region 402a of the set of active regions 402 of integrated circuit 100, 200, 400, 500, 600, 700A or 700B. In some embodiments, active region pattern 304a is usable to manufacture corresponding active region 404a of the set of active regions 404 of integrated circuit 100, 200, 400, 500, 600, 700A or 700B.

In some embodiments, the set of active region patterns 302 and 304 are referred to as an oxide diffusion (OD) region which defines the source or drain diffusion regions of at least integrated circuit 100, 200, 400, 500, 600, 700A or 700B or layout design 300. In some embodiments, the set of active region patterns 402 and 404 have a height W1a in the second direction Y.

In some embodiments, active region pattern 302a is usable to manufacture source and drain regions of NFET transistors of integrated circuits 100, 200, 400, 500, 600, 700A or 700B, and active region pattern 304a is usable to manufacture source and drain regions of PFET transistors of integrated circuits 100, 200, 400, 500, 600, 700A or 700B.

In some embodiments, active region pattern 302a is usable to manufacture source and drain regions of PFET transistors of integrated circuits 100, 200, 400, 500, 600, 700A or 700B, and active region pattern 304a is usable to manufacture source and drain regions of NFET transistors of integrated circuits 100, 200, 400, 500, 600, 700A or 700B.

In some embodiments, the set of active region patterns 302 or 304 is located on a first layout level. In some embodiments, the first layout level corresponds to an active level or an OD level of one or more of layout design 300 or integrated circuits 100, 200, 400, 500, 600, 700A or 700B. In some embodiments, the OD level is above the BM0 and the BM1 level.

Other configurations, arrangements on other layout levels or quantities of patterns in the set of active region patterns 302 or 304 are within the scope of the present disclosure.

Layout design 300 further includes one or more gate patterns 306a, 306b, 306c, 306d, 306e or 306f (collectively referred to as a “set of gate patterns 306”), one or more gate patterns 308a, 308b, 308c, 308d, 308e or 308f (collectively referred to as a “set of gate patterns 308”) extending in the second direction Y.

The set of gate patterns 306 is above the set of gate patterns 308.

At least one of gate patterns 306a, 306b, 306c, 306d, 306e or 306f is separated from another of at least one of gate patterns 306a, 306b, 306c, 306d, 306e or 306f in the first direction X.

At least one of gate patterns 308a, 308b, 308c, 308d, 308e or 308f is separated from another of at least one of gate patterns 308a, 308b, 308c, 308d, 308e or 308f in the first direction X.

The set of gate patterns 306 is usable to manufacture a corresponding set of gates 406 of integrated circuit 100, 200, 400, 500, 600, 700A or 700B. The set of gate patterns 308 is usable to manufacture a corresponding set of gates 408 of integrated circuit 100, 200, 400, 500, 600, 700A or 700B.

In some embodiments, gate patterns 306a, 306b, 306c, 306d, 306e or 306f are usable to manufacture corresponding gates 406a, 406b, 406c, 406d, 406e or 406f of the set of gates 406 of integrated circuit 100, 200, 400, 500, 600, 700A or 700B. In some embodiments, gate patterns 308a, 308b, 308c, 308d, 308e or 308f are usable to manufacture corresponding gates 408a, 408b, 408c, 408d, 408e or 408f of the set of gates 408 of integrated circuit 100, 200, 400, 500, 600, 700A or 700B.

In some embodiments, at least one of the set of gates 406 or 408 are located on the front-side 403a of integrated circuit 100, 200, 400, 500, 600, 700A or 700B.

In some embodiments, each of the gate patterns in the set of gate patterns 306 and 308 is shown in FIGS. 3C-3D with labels “N1-1, P1-1, N2-1, P2-1, N3-1, P3-1, N4-1, P4-1” that identify corresponding transistors of FIG. 1 manufactured by the corresponding gate pattern in FIGS. 3A-3D, and are omitted for brevity.

In some embodiments, the set of gate patterns 306 or 308 encapsulate the set of active region patterns 302 and 304. In some embodiments, a portion of the set of gate patterns 306 or 308 is above the set of active region patterns 302 and 304. In some embodiments, another portion of the set of gate patterns 306 or 308 is below the set of active region patterns 302 and 304.

The set of gate patterns 306 or 308 is positioned on a second layout level. In some embodiments, the second layout level is different from the first layout level. In some embodiments, the second layout level corresponds to the POLY level of one or more of layout design 300 or integrated circuits 100, 200, 400, 500, 600, 700A or 700B. In some embodiments, the POLY level is above the BMD and the BM0 level.

Other configurations, arrangements on other layout levels or quantities of patterns in the set of gate patterns 306 or 308 are within the scope of the present disclosure.

Layout design 300 further includes one or more cut feature patterns 340a (collectively referred to as a “set of cut feature patterns 340”) extending in at least one of the first direction or the second direction Y.

In some embodiments, the set of cut feature patterns 340 is above or below the set of gate patterns 306 or 308.

At least one cut feature pattern in the set of cut feature patterns 340 is separated from another cut feature pattern in the set of cut feature pattern 340 in at least one of the first direction X or the second direction Y.

In some embodiments, the set of cut feature patterns 340 overlap at least a portion of a gate pattern of the set of gate patterns 306 or 308. In some embodiments, the set of cut feature patterns 340 overlaps other underlying patterns (not shown) of other layout levels (e.g., BM0, BMD, Active, MD, or the like) of layout design 300.

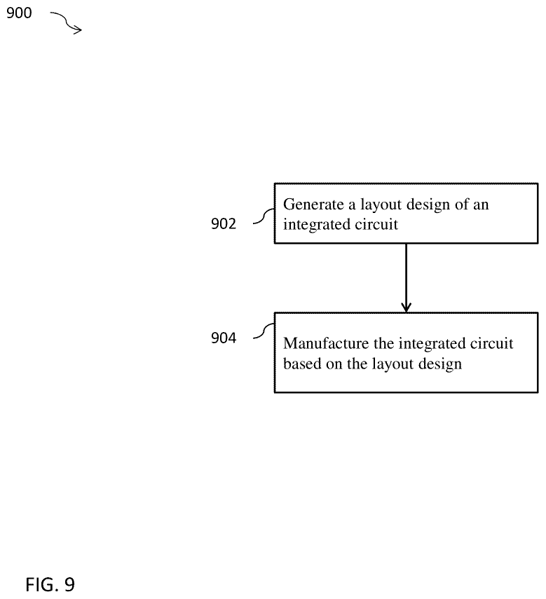

In some embodiments, cut feature patterns 340a identify corresponding locations of a corresponding removed gate portion of the set of removed gate portions that are removed in operation 904 of method 900 (FIG. 9), and replaced with a corresponding insulating region 440a of a set of insulating regions 440.

In some embodiments, cut feature pattern 340a is usable to separate gate 406c, 406d or 406e from other corresponding gates located in another cell.

Other configurations, arrangements on other layout levels or quantities of patterns in the set of cut feature patterns 340 are within the scope of the present disclosure. In some embodiments, at least one cut feature pattern of the set of cut feature patterns 340 is not included in layout design 300.

The set of cut feature patterns 340 is positioned on the second layout level.

Other configurations, arrangements on other layout levels or quantities of patterns in the set of cut feature patterns 340 are within the scope of the present disclosure.

Layout design 300 further includes one or more contact patterns 310a, 310b, 310c, 310d or 310e (collectively referred to as a “set of contact patterns 310”) extending in the second direction Y.

Each of the contact patterns of the set of contact patterns 310 is separated from an adjacent contact pattern of the set of contact patterns 310 in at least the first direction X.

The set of contact patterns 310 is usable to manufacture a corresponding set of contacts 410 of integrated circuit 100, 200, 400, 500, 600, 700A or 700B.

In some embodiments, contact pattern 310a, 310b, 310c, 310d or 310e of the set of contact patterns 310 is usable to manufacture corresponding contact 410a, 410b, 410c, 410d or 410e of the set of contact patterns 410. In some embodiments, the set of contact patterns 310 is also referred to as a set of metal over diffusion (MD) patterns.

In some embodiments, at least one of contact pattern 310a, 310b, 310c, 310d or 310e of the set of contact patterns 310 is usable to manufacture source or drain terminals of one of the NFET or PFET transistors of integrated circuit 100, 200, 400, 500, 600, 700A or 700B.

In some embodiments, contact pattern 310a is usable to manufacture a source terminal of NFET transistor N4-1, contact pattern 310b is usable to manufacture a drain terminal of NFET transistor N4-1 and a source terminal of NFET transistor N3-1, contact pattern 310c is usable to manufacture a drain terminal of NFET transistor N3-1 and a drain terminal of NFET transistor N1-1, contact pattern 310d is usable to manufacture a source terminal of NFET transistor N1-1 and a drain terminal of NFET transistor N2-1, and contact pattern 310e is usable to manufacture a source terminal of NFET transistor N2-1.

In some embodiments, the set of contact patterns 310 overlaps the set of active region patterns 302 or 304. The set of contact patterns 310 is located on a third layout level. In some embodiments, the third layout level corresponds to the contact level or an MD level of one or more of layout design 300 or integrated circuits 100, 200, 400, 500, 600, 700A or 700B. In some embodiments, the third layout level is different from at least one of the first layout level or the second layout level. Other configurations, arrangements on other layout levels or quantities of patterns in the set of contact patterns 310 are within the scope of the present disclosure.

Layout design 300 further includes one or more contact patterns 312a, 312b, 312c, 312d or 312e (collectively referred to as a “set of contact patterns 312”) extending in the second direction Y.

Each of the contact patterns of the set of contact patterns 312 is separated from an adjacent contact pattern of the set of contact patterns 312 in at least the first direction X.

The set of contact patterns 310 and 312 are separated from one another in the third direction Z. In some embodiments, contact patterns 310a and 312a are separated from one another in the third direction Z. In some embodiments, contact patterns 310b and 312b are separated from one another in the third direction Z. In some embodiments, contact patterns 310c and 312c are separated from one another in the third direction Z. In some embodiments, contact patterns 310d and 312d are separated from one another in the third direction Z. In some embodiments, contact patterns 310e and 312e are separated from one another in the third direction Z.

The set of contact patterns 312 is usable to manufacture a corresponding set of contacts 412 of integrated circuit 100, 200, 400, 500, 600, 700A or 700B.

In some embodiments, contact pattern 312a, 312b, 312c, 312d or 312e of the set of contact patterns 312 is usable to manufacture corresponding contact 412a, 412b, 412c, 412d or 412e of the set of contacts 412. In some embodiments, the set of contacts 412 are on a front-side 403a of integrated circuit 400. In some embodiments, a back-side 403b of integrated circuit 400 is opposite from the front-side of integrated circuit 400. In some embodiments, the set of contacts patterns 312 is also referred to as a set of back-side MD (BMD) patterns.

In some embodiments, contact pattern 312a is usable to manufacture a drain terminal of PFET transistor P4-1, contact pattern 312b is usable to manufacture a source terminal of PFET transistor P4-1 and a source terminal of PFET transistor P2-1, contact pattern 312c is usable to manufacture a drain terminal of PFET transistor P2-1 and a source terminal of PFET transistor P1-1, contact pattern 312d is usable to manufacture a drain terminal of PFET transistor P1-1 and a drain terminal of PFET transistor P3-1, and contact pattern 312e is usable to manufacture a source terminal of PFET transistor P3-1.

In some embodiments, the set of contact patterns 312 are overlapped by the set of active region patterns 302 or 304. The set of contact patterns 312 is located on a fourth layout level. In some embodiments, the fourth layout level corresponds to the back-side contact level or a back-side MD (BMD) level of one or more of layout design 300 or integrated circuits 100, 200, 400, 500, 600, 700A or 700B. In some embodiments, the fourth layout level is different from at least one of the first layout level, the second layout level or the third layout level.

In some embodiments, the BMD level is above the BM0 level. In some embodiments, the BMD level is above the front-side 403a of integrated circuit 400. In some embodiments, the BMD level is below the OD level, the POLY level, the MD level, the M0 level and the M1 level.

Other configurations, arrangements on other layout levels or quantities of patterns in the set of contact patterns 312 are within the scope of the present disclosure.

Layout design 300 further includes one or more conductive feature patterns 316a (collectively referred to as a “set of conductive feature patterns 316”) extending in the second direction Y.

Each of the conductive feature patterns of the set of conductive feature patterns 316 is separated from an adjacent conductive feature pattern of the set of conductive feature patterns 316 in at least the first direction X or the second direction Y.

In some embodiments, the set of conductive feature patterns 316 is overlapped by at least one contact pattern in the set of contact patterns 310. In some embodiments, the set of conductive feature patterns 316 overlaps at least one contact pattern in the set of contact patterns 312.

In some embodiments, the set of conductive feature patterns 316 is overlapped by the set of cut feature patterns 340. In some embodiments the set of conductive feature patterns 316 overlaps one or more gate patterns in the set of gate patterns 306 or 308.

In some embodiments, conductive feature pattern 316a is between gate patterns 308c and 308e.

In some embodiments the set of conductive feature patterns 316 is between the set of active regions 302 or 304 and the cell boundary 301b.

In some embodiments, conductive feature pattern 316a includes one or more separate discontinuous patterns. In some embodiments, conductive feature pattern 316b includes one or more separate discontinuous patterns.

The set of conductive feature patterns 316 is usable to manufacture a corresponding set of conductors 416 of integrated circuit 100, 200, 400, 500, 600, 700A or 700B.

In some embodiments, conductive feature pattern 316a of the set of conductive feature patterns 316 is usable to manufacture corresponding conductor 416a of the set of conductors 416. In some embodiments, the set of conductors 416 are on a front-side 403a of integrated circuit 400. In some embodiments, the set of contacts patterns 316 is also referred to as a set of via local interconnect (VLI) patterns.

In some embodiments, at least one of conductive feature pattern 316a of the set of conductive feature patterns 316 is usable to manufacture interconnect structures usable to connect at least source or drain terminals of one of the NFET or PFET transistors of integrated circuit 100, 200, 400, 500, 600, 700A or 700B with at least source or drain terminals of another one of the NFET or PFET transistors of integrated circuit 100, 200, 400, 500, 600, 700A or 700B.

In some embodiments, at least a first portion of the set of conductive feature patterns 316 are overlapped by one or more of the contact patterns in the set of contact patterns 310. In some embodiments, at least a first portion of conductive feature pattern 316a of the set of conductive feature patterns 316 is overlapped by contact pattern 310c of the set of contact patterns 310. In some embodiments, at least a first portion of conductive feature pattern 316a of the set of conductive feature patterns 316 is coplanar with contact pattern 310c of the set of contact patterns 310.

In some embodiments, at least a second portion of the set of conductive feature patterns 316 is between one or more of the contact patterns in the set of contact patterns 310 and one or more of the contact patterns in the set of contact patterns 312.

In some embodiments, at least a third portion of the set of conductive feature patterns 316 overlaps one or more of the contact patterns in the set of contact patterns 312. In some embodiments, at least a third portion of conductive feature pattern 316a of the set of conductive feature patterns 316 overlaps contact pattern 312d of the set of contact patterns 312. In some embodiments, at least a third portion of conductive feature pattern 316a of the set of conductive feature patterns 316 is coplanar with contact pattern 312d of the set of contact patterns 312.

In some embodiments, the set of conductive feature patterns 316 is within the set of cut feature patterns 340.

The set of conductive feature patterns 316 is located on a fifth layout level. In some embodiments, the fifth layout level corresponds to the VLI level of one or more of layout design 300 or integrated circuits 100, 200, 400, 500, 600, 700A or 700B. In some embodiments, the fifth layout level is different from at least the first layout level.

In some embodiments, the VLI level includes the MD level and the BMD level. In some embodiments, the VLI level includes the POLY level. In some embodiments, the VLI level is below the M0 level and the M1 level. In some embodiments, the VLI level is above the BM0 level.

Other configurations, arrangements on other layout levels or quantities of patterns in the set of conductive feature patterns 316 are within the scope of the present disclosure.

Layout design 300 further includes one or more insulating feature patterns 318a (collectively referred to as a “set of insulating feature patterns 318”) extending in at least the first direction X or the second direction Y.

Each of the insulating feature patterns of the set of insulating feature patterns 318 is separated from an adjacent insulating feature pattern of the set of insulating feature patterns 318 in at least the first direction X or the second direction Y.

The set of insulating feature patterns 318 is usable to manufacture a corresponding set of insulating regions 418 of integrated circuit 100, 200, 400, 500, 600, 700A or 700B.

In some embodiments, insulating feature pattern 318a of the set of insulating feature patterns 318 is usable to manufacture corresponding insulating region 418a of the set of insulating regions 418. The set of insulating regions 418 is on the front-side 403a of integrated circuit 400. Insulating region 418a is on the front-side 403a of integrated circuit 400. In some embodiments, the set of insulating feature patterns 318 is also referred to as a set of CVLI patterns. In some embodiments, the set of insulating regions 418 is also referred to as a set of CVLIs.

In some embodiments, at least one of insulating feature pattern 318a of the set of insulating feature patterns 318 is usable to manufacture an insulating region usable to cover at least a source or drain terminal of the NFET or PFET transistors of integrated circuit 100, 200, 400, 500, 600, 700A or 700B.

In some embodiments, the set of insulating feature patterns 318 overlaps one or more of the set of gate patterns 306, the set of gate patterns 308, the set of cut feature patterns 340, the set of contacts 312 or the set of conductive feature patterns 316.

In some embodiments, insulating feature pattern 318a overlaps at least one of gate pattern 306c, gate pattern 306d, gate pattern 306e, gate pattern 308c, gate pattern 308d, gate pattern 308e, cut feature pattern 340a, contact pattern 412d or conductive feature pattern 316a.

In some embodiments, the set of insulating feature patterns 318 is within the set of cut feature patterns 340.

The set of insulating feature patterns 318 is located on a sixth layout level. In some embodiments, the sixth layout level corresponds to the CVLI level of one or more of layout design 300 or 600 or integrated circuits 100, 200, 400, 500, 600, 700A or 700B. In some embodiments, the sixth layout level is different from at least the first layout level. In some embodiments, the CVLI level is between the M0 level and at least one of the OD level, the POLY level or the MD level. In some embodiments, the CVLI level is above at least one of the OD level, the BMD level or the VLI level. In some embodiments, the CVLI level is below the M0 level.

Other configurations, arrangements on other layout levels or quantities of patterns in the set of insulating feature patterns 318 are within the scope of the present disclosure.

Layout design 300 further includes one or more conductive feature patterns 330a, 330b, 330c or 330d (collectively referred to as a “set of conductive feature patterns 330”) extending in the first direction X.

Each conductive feature pattern in the set of conductive feature patterns 330 is separated from another conductive feature pattern in the set of conductive feature patterns 330 in first direction X or the second direction Y.

Conductive feature pattern 330c includes one or more of conductive feature patterns 330c1, 330c2 or 330c3. At least one of conductive feature pattern 330c1, 330c2 or 330c3 is separated from at least another of conductive feature pattern 330c1, 330c2 or 330c3 in the first direction X.

Conductive feature pattern 330d includes one or more of conductive feature patterns 330d1 or 330d2. At least one of conductive feature pattern 330d1 or 330d2 is separated from at least another of conductive feature pattern 330d1 or 330d2 in the first direction X.

The set of conductive feature patterns 330 overlap at least one of the set of active region patterns 302 or 304, the set of gate patterns 306 or 308, the set of cut feature patterns 340, the set of contact patterns 310 or 312, the set of conductive feature patterns 316 or the set of insulating feature patterns 318.

The set of conductive feature patterns 330 is usable to manufacture a corresponding set of conductors 430 of integrated circuit 100, 200, 400, 500, 600, 700A or 700B. Conductive feature patterns 330a, 330b, 330c or 330d are usable to manufacture corresponding conductors 430a, 430b, 430c or 430d of integrated circuit 100, 200, 400, 500, 600, 700A or 700B. In some embodiments, at least one conductor of the set of conductors 430 is located on the front-side 403a of integrated circuit 100, 200, 400, 500, 600, 700A or 700B.

Conductive feature patterns 330c1, 330c2 or 330c3 are usable to manufacture corresponding conductors 430c1, 430c2 or 430c3 of integrated circuit 100, 200, 400, 500, 600, 700A or 700B.

Conductive feature patterns 330d1 or 330d2 are usable to manufacture corresponding conductors 430d1 or 430d2 of integrated circuit 100, 200, 400, 500, 600, 700A or 700B.

In some embodiments, the set of conductive feature patterns 330 is located on a seventh layout level. In some embodiments, the seventh layout level is different from at least one of the first layout level, the second layout level, the third layout level, the fourth layout level, the fifth layout level or the sixth layout level. In some embodiments, the seventh layout level corresponds to the M0 level of one or more of layout design 300 or integrated circuits 100, 200, 400, 500, 600, 700A or 700B. In some embodiments, the M0 level is above the OD level, the POLY level, the MD level, the BMD level, the VLI level, the CVLI level and the BM0 level.

In some embodiments, the set of conductive feature patterns 330 correspond to 4 M0 routing tracks. Other numbers of M0 routing tracks are within the scope of the present disclosure.

Other configurations, arrangements on other layout levels or quantities of patterns in the set of conductive feature patterns 330 are within the scope of the present disclosure.

Layout design 300 further includes one or more conductive feature patterns 332a, 332b or 332c (collectively referred to as a “set of conductive feature patterns 332”) extending in the first direction X.

Each conductive feature pattern in the set of conductive feature patterns 332 is separated from another conductive feature pattern in the set of conductive feature patterns 332 in the second direction Y.

The set of conductive feature patterns 332 is overlapped by at least one of the set of active region patterns 302 or 304, the set of gate patterns 306 or 308, the set of cut feature patterns 340, the set of contact patterns 310 or 312, the set of conductive feature patterns 316 or the set of insulating feature patterns 318.

The set of conductive feature patterns 330 and 332 are separated from one another in the third direction Z. In some embodiments, conductive feature patterns 330c and 332b are separated from one another in the third direction Z. In some embodiments, conductive feature patterns 330d and 332c are separated from one another in the third direction Z.

The set of conductive feature patterns 332 is usable to manufacture a corresponding set of conductors 432 of integrated circuit 100, 200, 400, 500, 600, 700A or 700B. Conductive feature patterns 332a, 332b or 332c are usable to manufacture corresponding conductors 432a, 432b or 432c of integrated circuit 100, 200, 400, 500, 600, 700A or 700B. In some embodiments, at least one conductor of the set of conductors 432 is located on the back-side 403b of integrated circuit 100, 200, 400, 500, 600, 700A or 700B.

In some embodiments, the set of conductive feature patterns 332 is located on an eighth layout level. In some embodiments, the eighth layout level is different from at least one of the first layout level, the second layout level, the third layout level, the fourth layout level, the fifth layout level, the sixth layout level or the seventh layout level. In some embodiments, the eighth layout level corresponds to the BM0 level of one or more of layout design 300 or integrated circuits 100, 200, 400, 500, 600, 700A or 700B. In some embodiments, the BM0 level is below the OD level, the POLY level, the MD level, the BMD level, the VLI level, the CVLI level and the M0 level.

In some embodiments, the set of conductive feature patterns 332 correspond to 3 BM0 routing tracks. Other numbers of BM0 routing tracks are within the scope of the present disclosure.

Other configurations, arrangements on other layout levels or quantities of patterns in the set of conductive feature patterns 332 are within the scope of the present disclosure.

Layout design 300 further includes one or more via patterns 320a, 320b, 320c (collectively referred to as a “set of via patterns 320”).

The set of via patterns 320 is usable to manufacture a corresponding set of vias 420 of integrated circuit 100, 200, 400, 500, 600, 700A or 700B. In some embodiments, via patterns 320a, 320b, 320c of the set of via patterns 320 are usable to manufacture corresponding vias 420a, 420b, 420c of the set of vias 420 of integrated circuit 100, 200, 400, 500, 600, 700A or 700B.

In some embodiments, the set of via patterns 320 is between the set of contact patterns 310 and the set of conductive feature patterns 330. Via pattern 320a is between contact pattern 310a and conductive feature pattern 330b. Via pattern 320b is between contact pattern 310e and conductive feature pattern 330b. Via pattern 320c is between contact pattern 310c and conductive feature pattern 330c2.

The set of via patterns 320 is positioned at a via over diffusion (VD) level of one or more of layout design 300 or integrated circuits 100, 200, 400, 500, 600, 700A or 700B. In some embodiments, the VD level is above the OD level, the POLY level, the MD level, the BMD level, the VLI level, the CVLI level and the M0 level. In some embodiments, the VD level is below the M0 level. In some embodiments, the VD level is between the MD level and the M0 level. In some embodiments, the VD level is between the third layout level and the seventh layout level. Other layout levels are within the scope of the present disclosure.

Other configurations, arrangements on other layout levels or quantities of patterns in at least set of via patterns 320 are within the scope of the present disclosure.

Layout design 300 further includes one or more via patterns 322a, 322b, 322c, 322d, 322e (collectively referred to as a “set of via patterns 322”).

The set of via patterns 322 is usable to manufacture a corresponding set of vias 422 of integrated circuit 100, 200, 400, 500, 600, 700A or 700B. In some embodiments, via patterns 322a, 322b, 322c, 322d, 322e of the set of via patterns 322 are usable to manufacture corresponding vias 422a, 422b, 422c, 422d, 422e of the set of vias 422 of integrated circuit 100, 200, 400, 500, 600, 700A or 700B.

In some embodiments, the set of via patterns 322 is between the set of contact patterns 312 and the set of conductive feature patterns 332. Via pattern 322a is between contact pattern 312a and conductive feature pattern 332b. Via pattern 322b is between contact pattern 312c and conductive feature pattern 332b. Via pattern 322c is between contact pattern 312e and conductive feature pattern 332b. Via pattern 322d is between contact pattern 312b and conductive feature pattern 332a. Via pattern 322e is between contact pattern 312b and conductive feature pattern 332c.

The set of via patterns 322 is positioned at a back-side via over diffusion (BVD) level of one or more of layout design 300 or integrated circuits 100, 200, 400, 500, 600, 700A or 700B. In some embodiments, the BVD level is below the OD level, the POLY level, the MD level, the BMD level, the VLI level, the CVLI level and the M0 level. In some embodiments, the BVD level is above the BM0 level. In some embodiments, the BVD level is between the BMD level and the BM0 level. In some embodiments, the BVD level is between the fourth layout level and the eighth layout level. Other layout levels are within the scope of the present disclosure.

Other configurations, arrangements on other layout levels or quantities of patterns in at least set of via patterns 322 are within the scope of the present disclosure.

Layout design 300 further includes one or more via patterns 324a, 324b, 324c, 324d (collectively referred to as a “set of via patterns 324”).

The set of via patterns 324 is usable to manufacture a corresponding set of vias 424 of integrated circuit 100, 200, 400, 500, 600, 700A or 700B. In some embodiments, via patterns 324a, 324b, 324c, 324d of the set of via patterns 324 are usable to manufacture corresponding vias 424a, 424b, 424c, 424d of the set of vias 424 of integrated circuit 100, 200, 400, 500, 600, 700A or 700B.

In some embodiments, the set of via patterns 324 is between the set of gate patterns 306 and the set of conductive feature patterns 330.

Via pattern 324a is between gate pattern 306b and conductive feature pattern 330c1. Via pattern 324b is between gate pattern 306c and conductive feature pattern 330d1. Via pattern 324c is between gate pattern 306d and conductive feature pattern 330d2. Via pattern 324d is between gate pattern 306e and conductive feature pattern 330c3.

The set of via patterns 324 is positioned at a via over gate (VG) level of one or more of layout design 300 or integrated circuits 100, 200, 400, 500, 600, 700A or 700B. In some embodiments, the VG level is above the OD level, the POLY level, the MD level, the BMD level, the VLI level, the CVLI level, the BM0 level and the BM1 level. In some embodiments, the VG level is below the M0 level. In some embodiments, the VG level is between the POLY level and the M0 level. In some embodiments, the VG level is between the second layout level and the seventh layout level. Other layout levels are within the scope of the present disclosure.

Other configurations, arrangements on other layout levels or quantities of patterns in at least set of via patterns 324 are within the scope of the present disclosure.

Layout design 300 further includes one or more conductive feature patterns 360a, 360b, 360c, 360d, 360e (collectively referred to as a “set of conductive feature patterns 360”) extending in the second direction Y.

Each conductive feature pattern in the set of conductive feature patterns 360 is separated from another conductive feature pattern in the set of conductive feature patterns 360 in first direction X or the second direction Y.

The set of conductive feature patterns 360 overlap at least one of the set of active region patterns 302 or 304, the set of gate patterns 306 or 308, the set of cut feature patterns 340, the set of contact patterns 310 or 312, the set of conductive feature patterns 316, the set of insulating feature patterns 318, the set of conductive feature patterns 330 or 332, or the set of via patterns 320, 322, 324 or 350.

The set of conductive feature patterns 360 is usable to manufacture a corresponding set of conductors 460 of integrated circuit 100, 200, 400, 500, 600, 700A or 700B. Conductive feature patterns 360a, 360b, 360c, 360d, 360e are usable to manufacture corresponding conductors 460a, 460b, 460c, 460d, 460e of integrated circuit 100, 200, 400, 500, 600, 700A or 700B. In some embodiments, at least one conductor of the set of conductors 460 is located on the front-side 403a of integrated circuit 100, 200, 400, 500, 600, 700A or 700B.

In some embodiments, the set of conductive feature patterns 360 is located on a ninth layout level. In some embodiments, the ninth layout level is different from at least one of the first layout level, the second layout level, the third layout level, the fourth layout level, the fifth layout level, the sixth layout level, the seventh layout level or the eighth layout level. In some embodiments, the ninth layout level corresponds to the M1 level of one or more of layout design 300 or integrated circuits 100, 200, 400, 500, 600, 700A or 700B. In some embodiments, the M1 level is above the OD level, the POLY level, the MD level, the M0 level, the BMD level, the VLI level, the CVLI level and the BM0 level.

In some embodiments, the set of conductive feature patterns 360 correspond to 5 M1 routing tracks. Other numbers of M1 routing tracks are within the scope of the present disclosure.

Other configurations, arrangements on other layout levels or quantities of patterns in the set of conductive feature patterns 360 are within the scope of the present disclosure.

Layout design 300 further includes one or more via patterns 350a, 350b, 350c, 350d, 350e (collectively referred to as a “set of via patterns 350”).

The set of via patterns 350 is usable to manufacture a corresponding set of vias 450 of integrated circuit 100, 200, 400, 500, 600, 700A or 700B. In some embodiments, via patterns 350a, 350b, 350c, 350d, 350e of the set of via patterns 350 are usable to manufacture corresponding vias 450a, 450b, 450c, 450d, 450e of the set of vias 450 of integrated circuit 100, 200, 400, 500, 600, 700A or 700B.

In some embodiments, the set of via patterns 350 is between the set of conductive feature patterns 330 and the set of conductive feature patterns 360. Via pattern 350a is between conductive feature pattern 330c1 and conductive feature pattern 360a. Via pattern 350b is between conductive feature pattern 330d1 and conductive feature pattern 360b. Via pattern 350c is between conductive feature pattern 330c2 and conductive feature pattern 360c. Via pattern 350d is between conductive feature pattern 330d2 and conductive feature pattern 360d. Via pattern 350e is between conductive feature pattern 330c3 and conductive feature pattern 360e.

The set of via patterns 350 is positioned at a via over M0 (V0) level of one or more of layout design 300 or integrated circuits 100, 200, 400, 500, 600, 700A or 700B. In some embodiments, the V0 level is above the OD level, the POLY level, the MD level, the BMD level, the VLI level, the CVLI level and the M0 level. In some embodiments, the V0 level is below the M1 level. In some embodiments, the V0 level is between the M1 level and the M0 level. In some embodiments, the V0 level is between the seventh layout level and the ninth layout level. Other layout levels are within the scope of the present disclosure.

Other configurations, arrangements on other layout levels or quantities of patterns in at least set of via patterns 350 are within the scope of the present disclosure.

In some embodiments, the set of cut feature patterns 340 is usable to remove portions of one or more gates of the set of gates 406 or 408 in a first region 311, and the set of conductive feature patterns 316 is usable to form a set of conductors 416 in the first region 311 where the portions of the one or more gates of the set of gates 406 or 408 are removed.

In some embodiments, the first region 311 is positioned along the cell boundary 301b. In some embodiments, by positioning the set of cut feature patterns 340 and the set of conductive feature patterns 316 along the cell boundary 301b of layout design 300, an offset distance in the second direction Y between the set of cut feature patterns 340 and the cell boundary 301a satisfies cut Poly (CPO) process limitations without causing additional offset distances thereby resulting in a height W1a in the second direction Y of the set of active region patterns 302 and 304 to be constant throughout cell 301 of layout design 300 resulting in improved performance compared to other approaches.

In some embodiments, by including the set of conductive feature patterns 316 in the first region 311 of layout design 300, the set of conductive feature patterns 316 can be usable as additional routing resources of layout design 300 compared to other approaches.

In some embodiments, by including the set of conductive feature patterns 316 in the first region 311 of layout design 300, the set of conductive feature patterns 316 and the set of contacts 310 and 312 can be usable to provide an electrical connection between one or more transistors of the set of active regions 304 and one or more transistors of the set of active regions 302 thereby resulting in additional routing resources of layout design 300 compared to other approaches.

In some embodiments, cut feature pattern 340a is usable to remove portions of one or more of gates 406c, 406d, 406e, 408c, 408d or 408e in the first region 311, and the conductive feature pattern 316a is usable to form conductor 416a in the first region 311 where the portions of one or more of gates 406c, 406d, 406e, 408c, 408d or 408e are removed. In some embodiments, by including conductive feature pattern 316a in the first region 311 of layout design 300, conductive feature pattern 316a and contacts 310c and 312d can be usable to provide an electrical connection between one or more transistors of active region 304a and one or more transistors of active region 302a thereby resulting in additional routing resources of layout design 300 compared to other approaches.

Other configurations, arrangements on other layout levels or quantities of patterns in layout design 300 are within the scope of the present disclosure.

FIGS. 4A-4G are diagrams of an integrated circuit 400, in accordance with some embodiments.

FIGS. 4A-4D are corresponding diagrams of corresponding portions 400A-400D of an integrated circuit 400, simplified for ease of illustration.

Portion 400A includes one or more features of integrated circuit 400 of the OD level, the POLY level, the CPO level, the MD level, the M0 level, the VG level, the VD level, the M1 level and the V0 level. Portion 400A is manufactured by portion 300A.

Portion 400B includes one or more features of integrated circuit 400 of the OD level, the POLY level, the CPO level, the BMD level, the VLI level, the CVLI level, the BM0 level and the BVD level. Portion 400B is manufactured by portion 300B.

Portion 400C includes one or more features of integrated circuit 400 of the OD level, the POLY level, the CPO level, the MD level, the M0 level, the VG level, the VD level, the M1 level and the V0 level. Portion 400C is manufactured by portion 300C. In some embodiments, portion 400C is portion 400A, but the labels in portions 400C and 400A are different from each other for ease of illustration.

Portion 400D include one or more features of integrated circuit 400 of the OD level, the POLY level, the CPO level, the BMD level, the VLI level, the CVLI level, the BM0 level and the BVD level. Portion 400D is manufactured by portion 300D. In some embodiments, portion 400D is portion 400B, but the labels in portions 400D and 400B are different from each other for ease of illustration.

FIGS. 4E-4G are corresponding cross-sectional views of integrated circuit 400, in accordance with some embodiments. FIG. 4E is a cross-sectional view of integrated circuit 400 as intersected by plane A1-A1′, in accordance with some embodiments. FIG. 4F is a cross-sectional view of integrated circuit 400 as intersected by plane B-B′, in accordance with some embodiments. FIG. 4G is a cross-sectional view of integrated circuit 400 as intersected by plane A2-A2′, in accordance with some embodiments.

Components that are the same or similar to those in one or more of FIGS. 1, 2, 3A-3D, 4A-4G, 5A-5D, 6A-6F, 7 and 8A-8B are given the same reference numbers, and detailed description thereof is thus omitted.

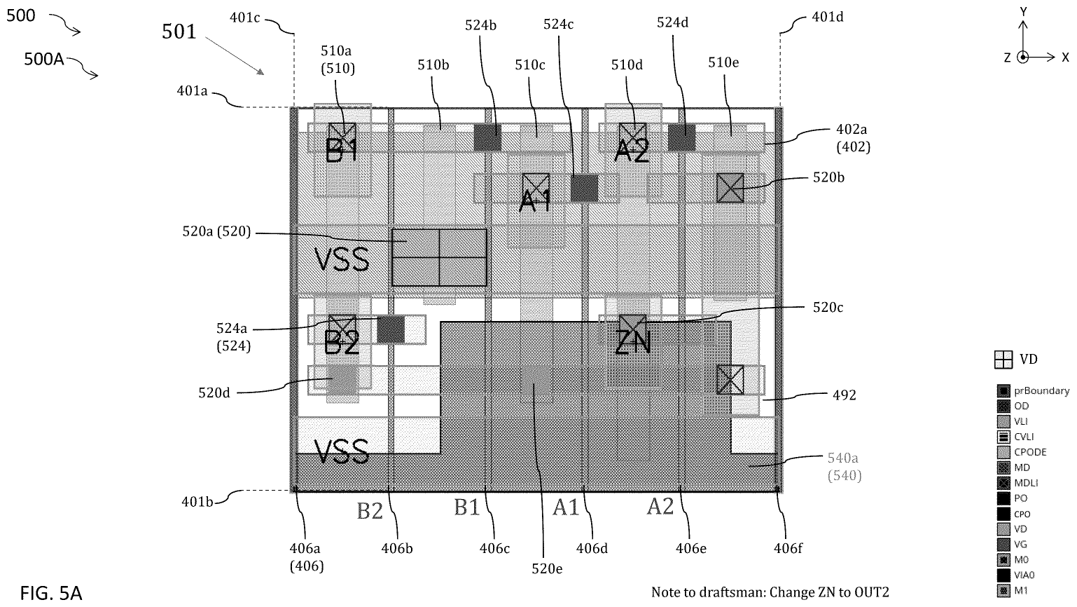

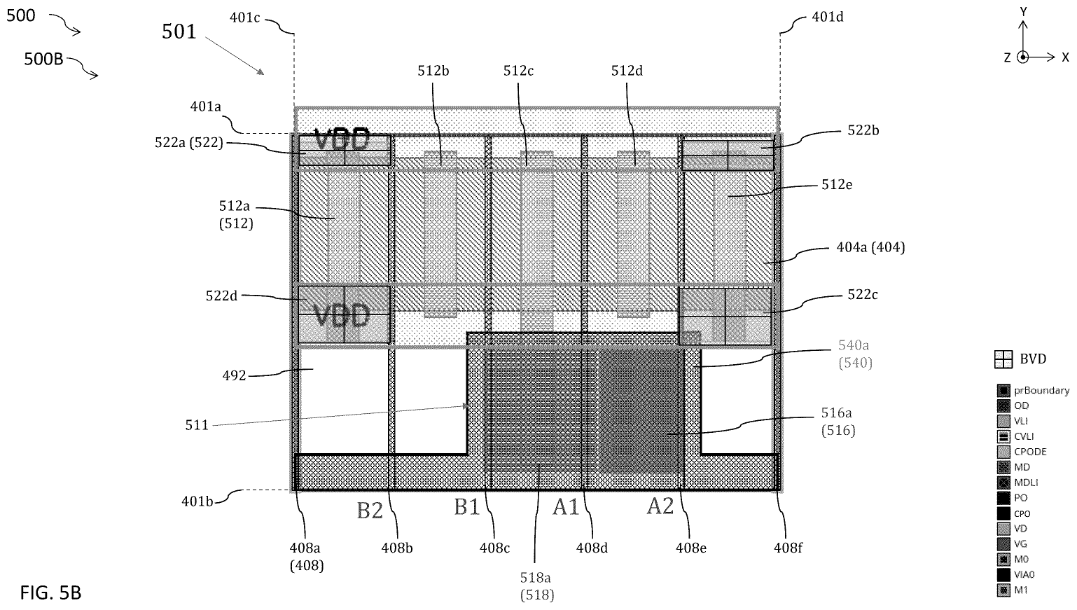

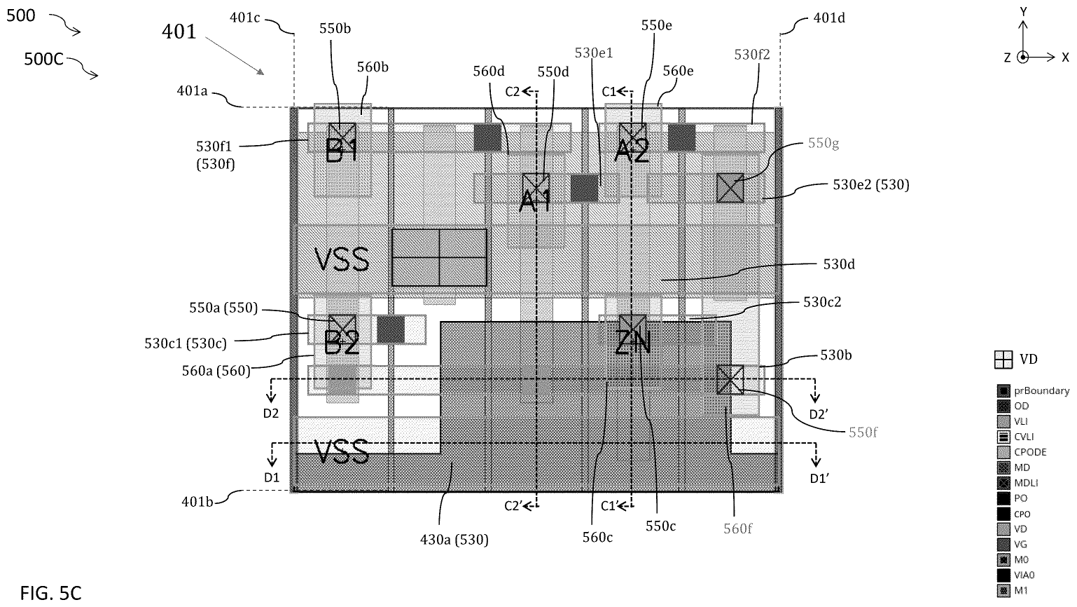

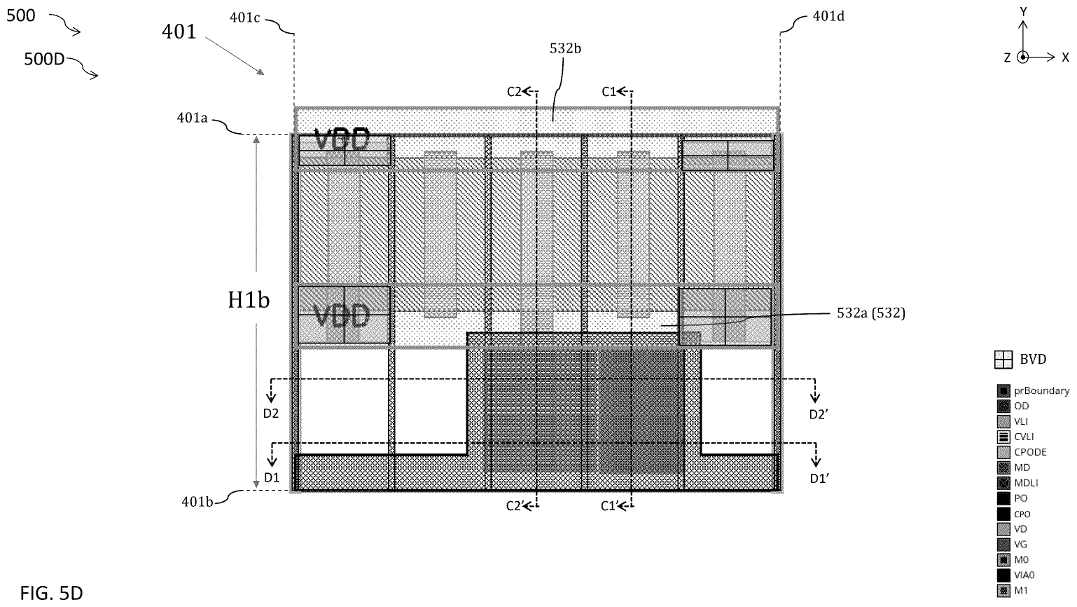

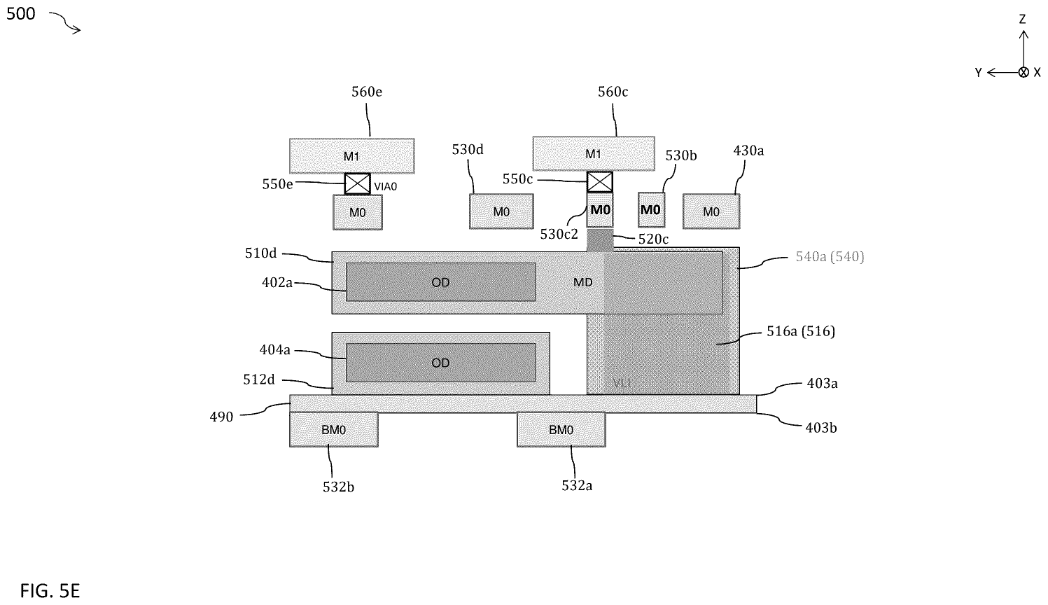

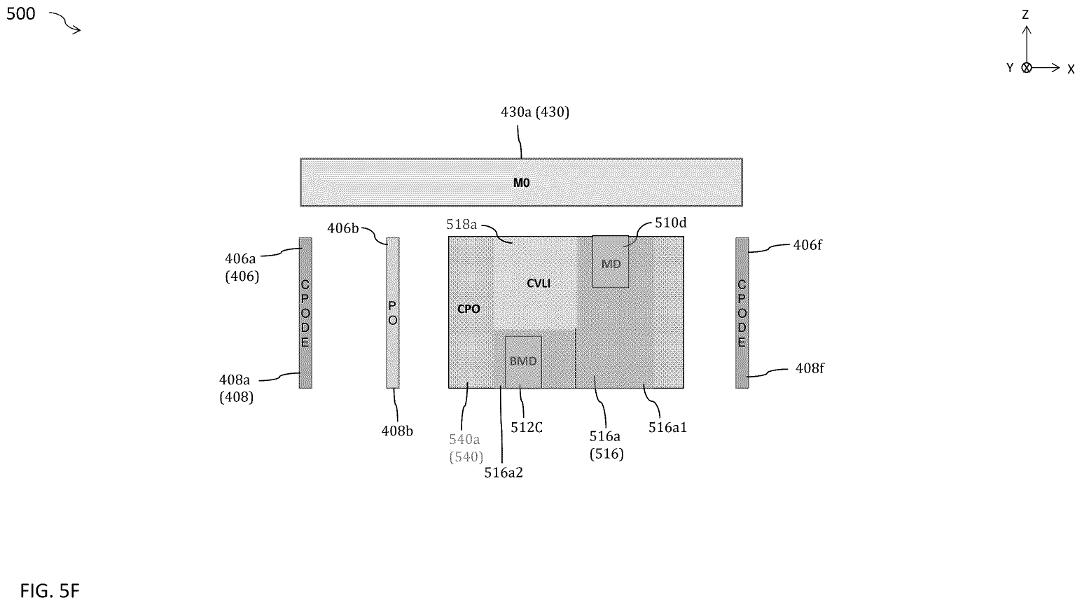

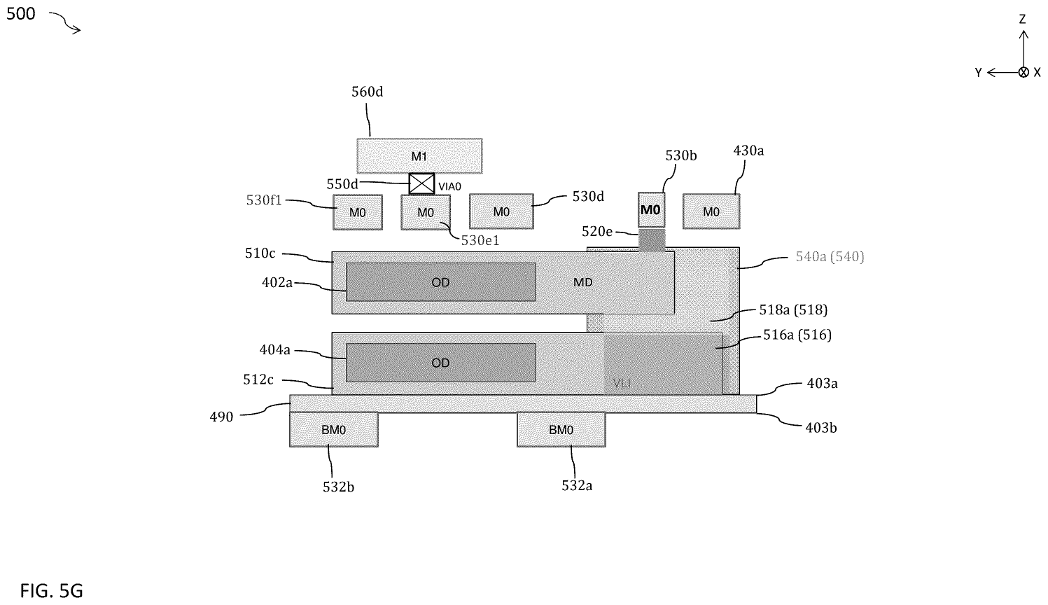

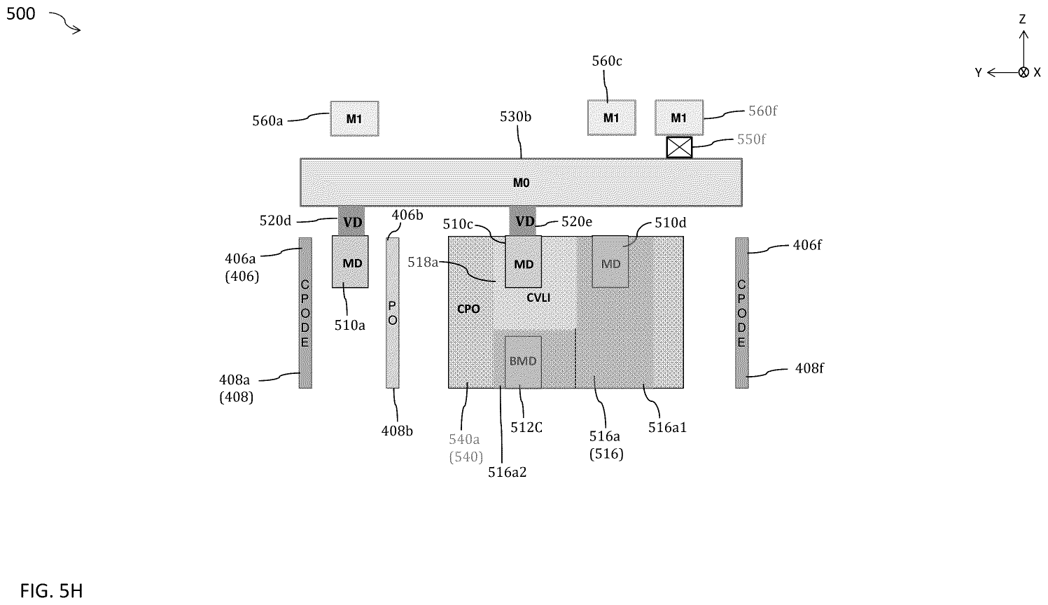

Integrated circuit 400 is manufactured by layout design 300. Integrated circuit 400 includes cell 401. Structural relationships including alignment, lengths and widths, as well as configurations and layers of integrated circuit 400, 600, 700 and 800A-800B are similar to the structural relationships and configurations and layers of layout design 300 of FIGS. 3A-3D and 5A-5D, and similar detailed description will not be described in at least FIGS. 4A-4G, for brevity. For example, in some embodiments, at least one or more widths, lengths or pitches of layout design 300 is similar to corresponding widths, lengths or pitches of integrated circuit 400, 600, 700 and 800A-800B, and similar detailed description is omitted for brevity. For example, in some embodiments, at least cell boundary 301a or 301b is similar to at least corresponding cell boundary 401a or 401b of integrated circuit 400, and similar detailed description is omitted for brevity.

Integrated circuit 400 includes at least the set of active regions 402 and 404, the set of gates 406 and 408, the set of insulating regions 440, the set of contacts 410, the set of contacts 412, the set of conductors 416, the set of insulating regions 418, the set of conductors 430, the set of conductors 432, the set of vias 420, the set of vias 422, the set of vias 424, the set of conductors 460, the set of vias 450, a substrate 490 and an insulating region 492.

The set of active regions 402 includes at least one of active region 402a.

The set of active regions 404 includes at least one of active region 404a.

The set of active regions 402 and 404 are embedded in substrate 490. Substrate 490 has a front-side 403a and a back-side 403b opposite from the front-side 403a. In some embodiments, at least the set of active regions 402 and 404, the set of gates 406 and 408 or the set of contacts 410 or 412, the set of conductors 416 and the set of insulating regions 418 are formed in the front-side 403a of substrate 490.

In some embodiments, the set of active regions 402 and 404 correspond to active regions of CFET transistors. In some embodiments, the set of active regions 402 and 404 correspond to nanosheet structures (not labelled) of nanosheet transistors. In some embodiments, the set of active regions 402 include drain regions and source regions grown by an epitaxial growth process. In some embodiments, the set of active regions 402 include drain regions and source regions that are grown with an epitaxial material at the corresponding drain regions and source regions.

Other transistor types are within the scope of the present disclosure. For example, in some embodiments, the set of active regions 402 corresponds to nanowire structures (not shown) of nanowire transistors. In some embodiments, the set of active regions 402 corresponds to planar structures (not shown) of planar transistors. In some embodiments, the set of active regions 402 corresponds to fin structures (not shown) of finFETs.

In some embodiments, active region 402a corresponds to source and drain regions of NFET transistors of integrated circuit 100, 200, 400, 500, 600, 700A or 700B, and active region 404a corresponds to source and drain regions of PFET transistors of integrated circuit 100, 200, 400, 500, 600, 700A or 700B.

In some embodiments, active region 402a corresponds to source and drain regions of PFET transistors of integrated circuit 100, 200, 400, 500, 600, 700A or 700B, and active region 404a corresponds to source and drain regions of NFET transistors of integrated circuit 100, 200, 400, 500, 600, 700A or 700B.

In some embodiments, at least active region 402a is an N-type doped S/D region, and at least active region 404a is a P-type doped S/D region embedded in a dielectric material of substrate 490. In some embodiments, at least active region 402a is a P-type doped S/D region, and at least active region 404a is an N-type doped S/D region embedded in a dielectric material of substrate 490.

Other configurations, arrangements on other layout levels or quantities of structures in the set of active regions 402 or 404 are within the scope of the present disclosure.

Insulating region 492 is configured to electrically isolate one or more elements of the set of active regions 402 and 404, the set of gates 406 and 408, the set of contacts 410, the set of contacts 412, the set of conductors 416, the set of insulating regions 418, the set of conductors 430, the set of conductors 432, the set of vias 420, the set of vias 422, the set of vias 424, the set of conductors 460, the set of vias 450 from one another. In some embodiments, insulating region 492 includes multiple insulating regions deposited at different times from each other during method 900 (FIG. 9). In some embodiments, insulating region 492 is a dielectric material. In some embodiments, the dielectric material includes silicon dioxide, silicon oxy-nitride, or the like.

Other configurations, arrangements on other layout levels or other numbers of portions in insulating region 492 are within the scope of the present disclosure.

The set of gates 406 includes at least one of gate 406a, 406b, 406c, 406d, 406e or 406f.

The set of gates 408 includes at least one of gate 408a, 408b, 408c, 408d, 408e or 408f.

The set of gates 406 and 408 correspond to one or more gates of transistors N1-1, P1-1, N2-1, P2-1, N3-1, P3-1, N4-1, P4-1 of integrated circuits 100, 200, 400, 500, 600, 700A or 700B. In some embodiments, each of the gates in the set of gates 406 and 408 are shown in FIGS. 4A-4G with labels “N1-1, P1-1, N2-1, P2-1, N3-1, P3-1, N4-1, P4-1” that identify corresponding transistors of FIG. 1 having corresponding gates in FIGS. 4A-4G, and are omitted for brevity.

In some embodiments, gate 406b is a gate of NFET transistor N4-1, gate 406c is a gate of NFET transistor N3-1, gate 406d is a gate of NFET transistor N1-1 and gate 406e is a gate of NFET transistor N2-1.

In some embodiments, gate 408b is a gate of PFET transistor P4-1, gate 408c is a gate of PFET transistor P2-1, gate 408d is a gate of PFET transistor P1-1 and gate 408e is a gate of PFET transistor P3-1.

In some embodiments, at least one of gate 406a, 406f, 408a or 408f is a dummy gate. In some embodiments a dummy gate is a gate of a non-functional transistor. In some embodiments, at least one of gate 406a, 406f, 408a or 408f is referred to as CPODE.

In some embodiments, gate 406a and gate 408a are coupled together. In some embodiments, gate 406a and gate 408a are part of the same continuous structure.

In some embodiments, gate 406c and gate 408c are coupled together. In some embodiments, gate 406c and gate 408c are part of the same continuous structure.

In some embodiments, gate 406d and gate 408d are coupled together. In some embodiments, gate 406d and gate 408d are part of the same continuous structure.

In some embodiments, gate 406e and gate 408e are coupled together. In some embodiments, gate 406e and gate 408e are part of the same continuous structure.

In some embodiments, gate 406f and gate 408f are coupled together. In some embodiments, gate 406f and gate 408f are part of the same continuous structure.

In some embodiments, one or more of gate 406a, 406b, 406c, 406d, 406e or 406f is separated from one or more of a corresponding gate 408a, 408b, 408c, 408d, 408e or 408f in the third direction Z by a corresponding insulating region (not shown).

In some embodiments, the set of gates 406 or 408 encapsulates the set of active regions 402 or 404.

Other configurations, arrangements on other layout levels or quantities of gates in the set of gates 406 and 408 are within the scope of the present disclosure.

The set of insulating regions 440 includes one or more of insulating region 440a.

In some embodiments, the set of insulating regions 440 replaces a set of removed gate portions in operation 904 of method 900 (FIG. 9). In some embodiments, insulating region 440a of the set of insulating regions 440 replaces a corresponding removed gate portion of the set of removed gate portions.

In some embodiments, one or more insulating regions 440a is a corresponding removed gate portion (not labelled), and similar detailed description is therefore omitted.

In some embodiments, the insulating region 440a separates at least one of gate 406c, 406d or 406e from a corresponding gate in an adjacent cell along cell boundary 401b.

In some embodiments, the insulating region 440a separates at least one of gate 408c, 408d or 408e from a corresponding gate in an adjacent cell along cell boundary 401b.

In some embodiments, the one or more insulating regions 440a is configured to electrically isolate the gates that are adjacent to the corresponding one or more insulating regions 440a.

In some embodiments, the set of insulating regions 440 includes multiple insulating regions deposited at different times from each other during method 900 (FIG. 9). In some embodiments, the set of insulating regions 440 is a dielectric material. In some embodiments, the dielectric material includes silicon dioxide, silicon oxy-nitride, or the like.

Other configurations, arrangements on other layout levels or quantities of insulating regions in the set of insulating regions 440 are within the scope of the present disclosure.

The set of contacts 410 includes at least one of contact 410a, 410b, 410c, 410d or 410e.

The set of contacts 412 includes at least one of contact 412a, 412b, 412c, 412d or 412e.

Each contact of the set of contacts 410 or 412 corresponds to one or more drain or source terminals of transistors N1-1, P1-1, N2-1, P2-1, N3-1, P3-1, N4-1, P4-1 of integrated circuits 100, 200, 400, 500, 600, 700A or 700B. In some embodiments, one or more contacts of the set of contacts 410 or 412 overlaps a pair of active regions of the set of active regions 402 and 404, thereby electrically coupling the pair of active regions of the set of active regions 402 and 404, and the source or drain of the corresponding transistors.

In some embodiments, the set of contacts 410 or 412 surrounds a portion of the set of active regions 402 or 404.

In some embodiments, contact 410a corresponds to the source terminal of NFET transistor N4-1.

In some embodiments, contact 410b corresponds to the drain terminal of NFET transistor N4-1 and a source terminal of NFET transistor N3-1.

In some embodiments, contact 410c corresponds to the drain terminal of NFET transistor N3-1 and a drain terminal of NFET transistor N1-1.

In some embodiments, contact 410d corresponds to the source terminal of NFET transistor N1-1 and a drain terminal of NFET transistor N2-1.

In some embodiments, contact 410e corresponds to the source terminal of NFET transistor N2-1.

In some embodiments, contact 412a corresponds to the drain terminal of PFET transistor P4-1.

In some embodiments, contact 412b corresponds to the source terminal of PFET transistor P4-1 and a source terminal of PFET transistor P2-1.

In some embodiments, contact 412c corresponds to the drain terminal of PFET transistor P2-1 and a source terminal of PFET transistor P1-1.

In some embodiments, contact 412d corresponds to the drain terminal of PFET transistor P1-1 and a drain terminal of PFET transistor P3-1.

In some embodiments, contact 412e corresponds to the source terminal of PFET transistor P3-1.

In some embodiments, contact 410c and contact 412d have a corresponding length in the second direction Y that is greater than a length of one or more contacts 410a, 410b, 410d, 410e, 412a, 412b, 412c or 412e.

Other configurations, arrangements on other layout levels or quantities of contacts in the set of contacts 410 and 412 are within the scope of the present disclosure.

The set of conductors 416 includes at least one of conductor 416a.

In some embodiments, conductor 416a is in direct contact with contact 410c and 412d. In some embodiments, conductor 416a electrically couples contact 410c and contact 412d together, thereby electrically coupling the drain terminal of NFET transistor N3-1 and the drain terminal of NFET transistor N1-1 with the drain terminal of PFET transistor P1-1 and the drain terminal of PFET transistor P3-1 together.

In some embodiments, the set of conductors 416 has an L shape. Other shapes for the set of conductors 416 are within the scope of the present disclosure.

Other configurations, arrangements on other layout levels or quantities of conductors in the set of conductors 416 are within the scope of the present disclosure.

In some embodiments, the set of insulating regions 418 includes at least one of insulating region 418a.

In some embodiments, insulating region 418a covers a recessed portion of conductor 416a. In some embodiments, the set of insulating regions 418 fills the recessed portion of the set of conductors 416 thereby causing a top surface of the set of insulating regions 418 to be coplanar with a top surface of the set of conductors 416

The set of insulating regions 418 is within the set of insulating regions 440.

In some embodiments, the set of insulating regions 418 includes multiple insulating regions deposited at different times from each other during method 900 (FIG. 9). In some embodiments, the set of insulating regions 418 is a dielectric material. In some embodiments, the dielectric material includes silicon dioxide, silicon oxy-nitride, or the like.

In some embodiments, the set of insulating regions 418 is a different material from the set of insulating regions 440. In some embodiments, the set of insulating regions 418 is a same material as the set of insulating regions 440.

In some embodiments, the set of insulating regions 418 has a rectangular shape. Other shapes for the set of insulating regions 418 are within the scope of the present disclosure.

Other configurations, arrangements on other layout levels or quantities of insulating regions in the set of insulating regions 418 are within the scope of the present disclosure.

The set of conductors 430 includes one or more conductors 430a, 430b, 430c or 430d.

The set of conductors 432 includes one or more conductors 432a, 432b or 432c.

Conductor 430c includes one or more of conductors 430c1, 430c2 or 430c3.

Conductor 430d includes one or more of conductors 430d1 or 430d2.

The set of conductors 430 is M0 routing tracks.

The set of conductors 432 is BM0 routing tracks.

In some embodiments, the set of conductors 430 and 432 are routing tracks in other layers. In some embodiments, the set of conductors 430 corresponds to 4 M0 routing tracks. In some embodiments, the set of conductors 432 corresponds to 3 BM0 routing tracks.

In some embodiments, the set of conductors 430 is configured to supply the reference supply voltage VSS. In some embodiments, the set of conductors 430 is configured to electrically couple one or more drain/source terminals with at least one of a gate or another drain/source terminal.

In some embodiments, the set of conductors 432 is configured to supply the supply voltage VDD. In some embodiments, the set of conductors 432 is configured to electrically couple one or more drain/source terminals with at least one of a gate or another drain/source terminal.

In some embodiments, conductor 430a is configured to supply the reference supply voltage VSS, and conductor 430b is configured to supply the reference supply voltage VSS.

In some embodiments, conductor 432a is configured to supply the supply voltage VDD, and conductor 432c is configured to supply the supply voltage VDD.

In some embodiments, conductor 432b is configured to electrically couple the drain terminal of PFET transistor P4-1, the drain terminal of PFET transistor P2-1, the source terminal of PFET transistor P1-1 and the source terminal of PFET transistor P3-1 together.

Other configurations, arrangements on other layout levels or quantities of conductors in the set of conductors 430 and 432 are within the scope of the present disclosure.

The set of vias 420 includes one or more of vias 420a, 420b or 420c.

The set of vias 422 includes one or more of vias 422a, 422b, 422c, 422d or 422e.

The set of vias 424 includes one or more of vias 424a, 424b, 424c or 424d.

The set of vias 420 is configured to electrically couple a corresponding source or drain region of the set of active regions 402 to the set of conductors 430 by the set of contacts 410, and vice versa. The set of vias 420 is between the set of contacts 410 and the set of conductors 430.

The set of vias 422 is configured to electrically couple a corresponding source or drain region of the set of active regions 404 to the set of conductors 432 by the set of contacts 412, and vice versa. The set of vias 422 is between the set of contacts 412 and the set of conductors 432.

The set of vias 424 is configured to electrically couple one or more gates of the set of gates 406 to the set of conductors 430, and vice versa. The set of vias 424 is between the set of gates 406 and the set of conductors 430.

Via 420a electrically couples contact 410a and conductor 430b together. Via 420b electrically couples contact 410e and conductor 430b together. Via 420c electrically couples contact 410c and conductor 430c2 together.

Via 422a electrically couples contact 412a and conductor 432b together. Via 422b electrically couples contact 412c and conductor 432b together. Via 422c electrically couples contact 412e and conductor 432b together. Via 422d electrically couples contact 412b and conductor 432a together. Via 422e electrically couples contact 412b and conductor 432c together.

Via 424a electrically couples gate 406b and conductor 430c1 together. Via 424b electrically couples gate 406c and conductor 430d1 together. Via 424c electrically couples gate 406d and conductor 430d2 together. Via 424d electrically couples gate 406e and conductor 430c3 together.

In some embodiments, at least one width in the first direction X of a via of the set of vias 420, 422, 424 or 450 is equal to at least one width in the first direction X of another via of the set of vias 420, 422, 424 or 450.

In some embodiments, at least one width in the first direction X of a via of the set of vias 420, 422, 424 or 450 is different from at least one width in the first direction X of another via of the set of vias 420, 422, 424 or 450.

Other configurations, arrangements on other layout levels or quantities of vias in the set of vias 420, 422 and 424 are within the scope of the present disclosure.

The set of conductors 460 includes one or more conductors 460a, 460b, 460c, 460d or 460e.

The set of conductors 460 is M1 routing tracks.

In some embodiments, the set of conductors 460 are routing tracks in other layers. In some embodiments, the set of conductors 460 corresponds to 5 M1 routing tracks.

In some embodiments, the set of conductors 460 is configured as an input pin, and is configured to supply a gate signal B2, B1, A1 or A2 to the set of gates 406. In some embodiments, conductor 460a, 460b, 460d or 460e is configured as a corresponding input pin, and is configured to supply a corresponding gate signal B2, B1, A1 or A2 to corresponding gate 406b, 406c, 406d or 406e.

In some embodiments, the set of conductors 460 is configured as an output pin, and is configured to output the output signal OUT1. In some embodiments, conductor 460c is configured as a corresponding output pin, and is configured to output the corresponding output signal OUT1.

Other configurations, arrangements on other layout levels or quantities of conductors in the set of conductors 460 are within the scope of the present disclosure.

The set of vias 450 includes one or more of vias 450a, 450b, 450c, 450d or 450e.

The set of vias 450 is configured to electrically couple a corresponding conductor of the set of conductors 430 to the set of conductors 460, and vice versa. The set of vias 450 is between the set of conductors 430 and the set of conductors 460.

Via 450a electrically couples conductor 430c1 and conductor 460a together. Via 450b electrically couples conductor 430d1 and conductor 460b together. Via 450c electrically couples conductor 430c2 and conductor 460c together. Via 450d electrically couples conductor 430d2 and conductor 460d together. Via 450e electrically couples conductor 430c3 and conductor 460e together.

Other configurations, arrangements on other layout levels or quantities of vias in the set of vias 450 are within the scope of the present disclosure.

In some embodiments, at least one gate of the set of gates 406 or 408 are formed using a doped or non-doped polycrystalline silicon (or polysilicon). In some embodiments, at least one gate of the set of gates 406 or 408 include a metal, such as Al, Cu, W, Ti, Ta, TiN, TaN, NiSi, CoSi, other suitable conductive materials, or combinations thereof.

In some embodiments, at least one contact of the set of contacts 410, 412, 510 or 512, or at least one conductor of the set of conductors 416, 430, 432, 460, 516, 530, 532 or 560, or at least one via of the set of vias 420, 422, 424, 450, 520, 522, 524 or 550 includes one or more layers of a conductive material, a metal, a metal compound or a doped semiconductor. In some embodiments, the conductive material includes Tungsten, Cobalt, Ruthenium, Copper, or the like or combinations thereof. In some embodiments, a metal includes at least Cu (Copper), Co, W, Ru, Al, or the like. In some embodiments, a metal compound includes at least AlCu, W-TiN, TiSix, NiSix, TiN, TaN, or the like. In some embodiments, a doped semiconductor includes at least doped silicon, or the like.

In some embodiments, portions of one or more gates of the set of gates 406 or 408 are removed from a first region 411, and the set of insulating regions 440 and the set of conductors 416 are positioned within the first region 411. In some embodiments, by including the set of conductors 416 in the first region 411 of integrated circuit 400, a height W1b in the second direction Y of the set of active regions 402 and 404 is constant throughout cell 401 of integrated circuit 400 resulting in improved performance compared to other approaches.

In some embodiments, by including the set of conductors 416 in the first region 411 of integrated circuit 400, the set of conductors 416 can be usable as additional routing resources of integrated circuit 400 compared to other approaches.

In some embodiments, by including the set of conductors 416 in the first region 411 of integrated circuit 400, the set of conductors 416 and the set of contacts 410 and 412 can be usable to provide an electrical connection between one or more transistors of the set of active regions 404 and one or more transistors of the set of active regions 402 thereby resulting in additional routing resources of integrated circuit 400 compared to other approaches.

In some embodiments, by including conductor 416a in the first region 411 of integrated circuit 400, conductor 416a is in direct contact with contact 410c and 412d, and thereby electrically couples contact 410c and contact 412d together, thus electrically coupling the drain terminal of NFET transistor N3-1 and the drain terminal of NFET transistor N1-1 with the drain terminal of PFET transistor P1-1 and the drain terminal of PFET transistor P3-1 together, thereby resulting in additional routing resources of integrated circuit 400 compared to other approaches.

Other configurations or arrangements of integrated circuit 400 are within the scope of the present disclosure.

FIGS. 5A-5H are diagrams of an integrated circuit 500, in accordance with some embodiments.

FIGS. 5A-5D are corresponding diagrams of corresponding portions 500A-500D of an integrated circuit 500, simplified for ease of illustration.

Portion 500A includes one or more features of integrated circuit 500 of the OD level, the POLY level, the CPO level, the MD level, the M0 level, the VG level, the VD level, the M1 level and the V0 level. Portion 500A is manufactured by a layout similar to portion 300A, and similar detailed description is omitted for brevity.

Portion 500B includes one or more features of integrated circuit 500 of the OD level, the POLY level, the CPO level, the BMD level, the VLI level, the CVLI level, the BM0 level and the BVD level. Portion 500B is manufactured by a layout similar to portion 300B, and similar detailed description is omitted for brevity.

Portion 500C includes one or more features of integrated circuit 500 of the OD level, the POLY level, the CPO level, the MD level, the M0 level, the VG level, the VD level, the M1 level and the V0 level. Portion 500C is manufactured by a layout similar to portion 300C, and similar detailed description is omitted for brevity. In some embodiments, portion 500C is portion 500A, but the labels in portions 500C and 500A are different from each other for ease of illustration.

Portion 500D includes one or more features of integrated circuit 500 of the OD level, the POLY level, the CPO level, the BMD level, the VLI level, the CVLI level, the BM0 level and the BVD level. Portion 500D is manufactured by a layout similar to portion 300D, and similar detailed description is omitted for brevity. In some embodiments, portion 500D is portion 500B, but the labels in portions 500D and 500B are different from each other for ease of illustration.

FIG. 5E is a cross-sectional view of integrated circuit 500 as intersected by plane C1-C1′, in accordance with some embodiments.

FIG. 5F is a cross-sectional view of integrated circuit 500 as intersected by plane D1-D1′, in accordance with some embodiments. FIG. 5G is a cross-sectional view of integrated circuit 500 as intersected by plane C2-C2′, in accordance with some embodiments. FIG. 5H is a cross-sectional view of integrated circuit 500 as intersected by plane D2-D2′, in accordance with some embodiments.

In some embodiments, integrated circuit 500 is integrated circuit 200.

Integrated circuit 500 is manufactured by a corresponding layout design similar to integrated circuit 500. While integrated circuit 500 is described as an integrated circuit, integrated circuit 500 can also be a layout design similar to layout design 300, and similar detailed description will not be described in at least FIGS. 5A-5H, for brevity.

In some embodiments, integrated circuit 500 is manufactured by a layout design similar to layout design 300, and similar detailed description is therefore omitted. Structural relationships including alignment, lengths and widths, as well as configurations and layers of integrated circuit 500 are similar to the structural relationships and configurations and layers of integrated circuit 300 of FIGS. 3A-3D, and similar detailed description will not be described in at least FIGS. 5A-5H, for brevity.

Integrated circuit 500 is cell 501. Cell 501 is a variation of cell 401 of FIGS. 4A-4G, and similar detailed description is omitted for brevity.

Integrated circuit 500 is a variation of integrated circuit 400 of FIGS. 4A-4G, and similar detailed description is omitted for brevity.

In comparison with integrated circuit 400 of FIGS. 4A-4G, a set of contacts 510 replaces the set of contacts 410 of integrated circuit 400, a set of contacts 512 replaces the set of contacts 412 of integrated circuit 400, a set of conductors 516 replaces the set of conductors 416 of integrated circuit 400, a set of insulating regions 518 replaces the set of insulating region 418 of integrated circuit 400, a set of insulating regions 540 replaces the set of insulating regions 440 of integrated circuit 400, a set of vias 520 replaces the set of vias 420 of integrated circuit 400, a set of vias 522 replaces the set of vias 422 of integrated circuit 400, a set of vias 524 replaces the set of vias 424 of integrated circuit 400, a set of conductors 530 replaces the set of conductors 430 of integrated circuit 400, a set of conductors 532 replaces the set of conductors 432 of integrated circuit 400, a set of vias 550 replaces the set of vias 450 of integrated circuit 400, a set of conductors 560 replaces the set of conductors 460 of integrated circuit 400, and similar detailed description is omitted for brevity.

Integrated circuit 500 includes at least the set of active regions 402 and 404, the set of gates 406 and 408, a set of contacts 510, a set of contacts 512, a set of conductors 516, a set of insulating regions 518, a set of insulating regions 540, a set of vias 520, a set of vias 522, a set of vias 524, a set of conductors 530, a set of conductors 532, a set of vias 550, a set of conductors 560, a substrate 490 and an insulating region 492.

The set of gates 406 and 408 correspond to one or more gates of transistors N1-2, P1-2, N2-2, P2-2, N3-2, P3-2, N4-2, P4-2 of integrated circuits 200, 400, 500, 600, 700A or 700B. In some embodiments, each of the gates in the set of gates 406 and 408 are shown in FIGS. 5A-5H with labels “N1-2, P1-2, N2-2, P2-2, N3-2, P3-2, N4-2, P4-2” that identify corresponding transistors of FIG. 2 having corresponding gates in FIGS. 5A-5H, and are omitted for brevity.

As shown in FIGS. 5A-5D, gate 406b is a gate of NFET transistor N2-2, gate 406c is a gate of NFET transistor N4-2, gate 406d is a gate of NFET transistor N3-2 and gate 406e is a gate of NFET transistor N1-2, in accordance with some embodiments.

As shown in FIGS. 5A-5D, gate 408b is a gate of PFET transistor P4-2, gate 408c is a gate of PFET transistor P3-2, gate 408d is a gate of PFET transistor P1-2 and gate 408e is a gate of PFET transistor P2-2, in accordance with some embodiments.

The set of insulating regions 540 includes one or more of insulating region 540a.

In some embodiments, the set of insulating regions 540 replaces a set of removed gate portions in operation 904 of method 900 (FIG. 9). In some embodiments, insulating region 540a of the set of insulating regions 540 replaces a corresponding removed gate portion of the set of removed gate portions.

In some embodiments, one or more insulating regions 540a is a corresponding removed gate portion (not labelled), and similar detailed description is therefore omitted.

.

In some embodiments, the insulating region 540a separates at least one of gate 406c, 406d or 406e from a corresponding gate in an adjacent cell along cell boundary 401b.

In some embodiments, the insulating region 540a separates at least one of gate 408c, 408d or 408e from a corresponding gate in an adjacent cell along cell boundary 401b.

In some embodiments, the one or more insulating regions 540a is configured to electrically isolate the gates that are adjacent to the corresponding one or more insulating regions 540a.

In some embodiments, the set of insulating regions 540 includes multiple insulating regions deposited at different times from each other during method 900 (FIG. 9). In some embodiments, the set of insulating regions 540 is a dielectric material. In some embodiments, the dielectric material includes silicon dioxide, silicon oxy-nitride, or the like.

Other configurations, arrangements on other layout levels or quantities of insulating regions in the set of insulating regions 540 are within the scope of the present disclosure.

The set of contacts 510 includes at least one of contact 510a, 510b, 510c, 510d or 510e.

The set of contacts 512 includes at least one of contact 512a, 512b, 512c, 512d or 512e.

Each contact of the set of contacts 510 or 512 corresponds to one or more drain or source terminals of transistors N1-2, P1-2, N2-2, P2-2, N3-2, P3-2, N4-2, P4-2 of integrated circuits 200, 400, 500, 600, 700A or 700B.

In some embodiments, contact 510a corresponds to the drain terminal of NFET transistor N2-2.

In some embodiments, contact 510b corresponds to the source terminal of NFET transistor N2-2 and a source terminal of NFET transistor N4-2.

In some embodiments, contact 510c corresponds to the drain terminal of NFET transistor N4-2 and a source terminal of NFET transistor N3-2.

In some embodiments, contact 510d corresponds to the drain terminal of NFET transistor N3-2 and a drain terminal of NFET transistor N1-2.

In some embodiments, contact 510e corresponds to the source terminal of NFET transistor N1-2.

In some embodiments, contact 512a corresponds to the source terminal of PFET transistor P4-2.

In some embodiments, contact 512b corresponds to the drain terminal of PFET transistor P4-2 and a source terminal of PFET transistor P3-2.

In some embodiments, contact 512c corresponds to the drain terminal of PFET transistor P3-2 and a drain terminal of PFET transistor P1-2.

In some embodiments, contact 512d corresponds to the source terminal of PFET transistor P1-2 and a drain terminal of PFET transistor P2-2.

In some embodiments, contact 512e corresponds to the source terminal of PFET transistor P2-2.

In some embodiments, contact 510d and contact 512c have a corresponding length in the second direction Y that is greater than a length of one or more contacts 510a, 510b, 510d, 510e, 512a, 512b, 512c or 512e.

Other configurations, arrangements on other layout levels or quantities of contacts in the set of contacts 510 and 512 are within the scope of the present disclosure.

The set of conductors 516 includes at least one of conductor 516a.

In some embodiments, conductor 516a is in direct contact with contact 510d and 512c. In some embodiments, conductor 516a electrically couples contact 510d and contact 512c together, thereby electrically coupling the drain terminal of NFET transistor N3-2 and the drain terminal of NFET transistor N1-2 with the drain terminal of PFET transistor P1-2 and the drain terminal of PFET transistor P3-2 together.

In some embodiments, the set of conductors 516 has an L shape. Other shapes for the set of conductors 516 are within the scope of the present disclosure.

Other configurations, arrangements on other layout levels or quantities of conductors in the set of conductors 516 are within the scope of the present disclosure.

The set of insulating regions 518 includes at least one of insulating region 518a.

In some embodiments, insulating region 518a covers a recessed portion of conductor 516a. In some embodiments, the set of insulating regions 518 fills the recessed portion of the set of conductors 516 thereby causing a top surface of the set of insulating regions 518 to be coplanar with a top surface of the set of conductors 516 In some embodiments, the set of insulating regions 518 is within the set of insulating regions 540.

In some embodiments, the set of insulating regions 518 includes multiple insulating regions deposited at different times from each other during method 900 (FIG. 9). In some embodiments, the set of insulating regions 518 is a dielectric material. In some embodiments, the dielectric material includes silicon dioxide, silicon oxy-nitride, or the like.

In some embodiments, the set of insulating regions 518 is a different material from the set of insulating regions 540. In some embodiments, the set of insulating regions 518 is a same material as the set of insulating regions 540.

In some embodiments, the set of insulating regions 518 has a rectangular shape. Other shapes for the set of insulating regions 518 are within the scope of the present disclosure.

Other configurations, arrangements on other layout levels or quantities of insulating regions in the set of insulating regions 518 are within the scope of the present disclosure.

The set of conductors 530 includes one or more conductors 430a, 530b, 530c, 530d, 530e or 530f.

The set of conductors 532 includes one or more conductors 532a or 532b.

Conductor 530c includes one or more of conductors 530c1 or 530c2.

Conductor 530e includes one or more of conductors 530e1 or 530e2.

Conductor 530f includes one or more of conductors 530f1 or 530f2.

The set of conductors 530 is M0 routing tracks.

The set of conductors 532 is BM0 routing tracks.

In some embodiments, the set of conductors 530 and 532 are routing tracks in other layers. In some embodiments, the set of conductors 530 corresponds to 6 M0 routing tracks. In some embodiments, the set of conductors 532 corresponds to 2 BM0 routing tracks.

In some embodiments, conductor 430a is configured to supply the reference supply voltage VSS, and conductor 530d is configured to supply the reference supply voltage VSS.

In some embodiments, conductor 532a is configured to supply the supply voltage VDD, and conductor 532b is configured to supply the supply voltage VDD.

In some embodiments, at least conductors 530b and 530e2 are configured to electrically couple the drain terminal of NFET transistor N2-2, the drain terminal of NFET transistor N4-2, the source terminal of NFET transistor N3-2 and the source terminal of NFET transistor N1-2 together.

Other configurations, arrangements on other layout levels or quantities of conductors in the set of conductors 530 and 532 are within the scope of the present disclosure.

The set of vias 520 includes one or more of vias 520a, 520b, 520c, 520d or 520e.

The set of vias 522 includes one or more of vias 522a, 522b, 522c or 522d.

The set of vias 524 includes one or more of vias 524a, 524b, 524c or 524d.

The set of vias 520 is configured to electrically couple a corresponding source or drain region of the set of active regions 402 to the set of conductors 530 by the set of contacts 510, and vice versa. The set of vias 520 is between the set of contacts 510 and the set of conductors 530.

The set of vias 522 is configured to electrically couple a corresponding source or drain region of the set of active regions 404 to the set of conductors 532 by the set of contacts 512, and vice versa. The set of vias 522 is between the set of contacts 512 and the set of conductors 532.

The set of vias 524 is configured to electrically couple one or more gates of the set of gates 406 to the set of conductors 530, and vice versa. The set of vias 524 is between the set of gates 406 and the set of conductors 530.

Via 520a electrically couples contact 510b and conductor 530d together. Via 520b electrically couples contact 510e and conductor 530e2 together. Via 520c electrically couples contact 510d and conductor 530c2 together. Via 520d electrically couples contact 510a and conductor 530b together. Via 520e electrically couples contact 510c and conductor 530b together.

Via 522a electrically couples contact 512a and conductor 532b together. Via 522b electrically couples contact 512e and conductor 532b together. Via 522c electrically couples contact 512e and conductor 532a together. Via 522d electrically couples contact 512a and conductor 532a together.

Via 524a electrically couples gate 406b and conductor 530c1 together. Via 524b electrically couples gate 406c and conductor 530f1 together. Via 524c electrically couples gate 406d and conductor 530e1 together. Via 524d electrically couples gate 406e and conductor 530f2 together.

In some embodiments, at least one width in the first direction X of a via of the set of vias 520, 522, 524 or 550 is equal to at least one width in the first direction X of another via of the set of vias 520, 522, 524 or 550.

In some embodiments, at least one width in the first direction X of a via of the set of vias 520, 522, 524 or 550 is different from at least one width in the first direction X of another via of the set of vias 520, 522, 524 or 550.

Other configurations, arrangements on other layout levels or quantities of vias in the set of vias 520, 522 and 524 are within the scope of the present disclosure.

The set of conductors 560 includes one or more conductors 560a, 560b, 560c, 560d, 560e or 560f.

The set of conductors 560 is M1 routing tracks.

In some embodiments, the set of conductors 560 are routing tracks in other layers. In some embodiments, the set of conductors 560 corresponds to 4 M1 routing tracks.

In some embodiments, the set of conductors 560 is configured as an input pin, and is configured to supply a gate signal B2, B1, A1 or A2 to the set of gates 406. In some embodiments, conductor 560a, 560b, 560d or 560e is configured as a corresponding input pin, and is configured to supply a corresponding gate signal B2, B1, A1 or A2 to corresponding gate 406b, 406c, 406d or 406e.

In some embodiments, the set of conductors 560 is configured as an output pin, and is configured to output the output signal OUT2. In some embodiments, conductor 560c is configured as a corresponding output pin, and is configured to output the corresponding output signal OUT2.

In some embodiments, conductor 560f is configured to electrically couple at least conductors 530b and 530e2 together, thereby electrically coupling the drain terminal of NFET transistor N2-2, the drain terminal of NFET transistor N4-2, the source terminal of NFET transistor N3-2 and the source terminal of NFET transistor N1-2 together.

Other configurations, arrangements on other layout levels or quantities of conductors in the set of conductors 560 are within the scope of the present disclosure.

The set of vias 550 includes one or more of vias 550a, 550b, 550c, 550d, 550e, 550f or 550g.

The set of vias 550 is configured to electrically couple a corresponding conductor of the set of conductors 530 to the set of conductors 560, and vice versa. The set of vias 550 is between the set of conductors 530 and the set of conductors 560.

Via 550a electrically couples conductor 530c1 and conductor 560a together.

Via 550b electrically couples conductor 530f1 and conductor 560b together.

Via 550c electrically couples conductor 530c2 and conductor 560c together.

Via 550d electrically couples conductor 530e1 and conductor 560d together.

Via 550e electrically couples conductor 530f2 and conductor 560e together.

Via 550f electrically couples conductor 530b and conductor 560f together.

Via 550g electrically couples conductor 530e2 and conductor 560f together.

In some embodiments, conductor 560f is electrically coupled to conductors 530b and 530e2 by corresponding vias 550f and 550g.

Other configurations, arrangements on other layout levels or quantities of vias in the set of vias 550 are within the scope of the present disclosure.

The set of conductors 532 includes at least one of conductor 432a, 432b, 432c, 432d, 432e or 532f.

In comparison with integrated circuit 400, conductor 532f of the set of conductors 532 is similar to one or more of conductors 432a, 432b, 432c, 432d, 432e of the set of conductors 432, and similar detailed description is omitted for brevity.

The set of conductors 532 is BM0 routing tracks. In some embodiments, the set of conductors 532 is routing tracks in other layers. In some embodiments, the set of conductors 432 corresponds to 5 BM0 routing tracks. Other BM0 track assignments or numbers of BM0 tracks are within the scope of the present disclosure.

In some embodiments, conductor 532f is the read bit line RBL.

Other configurations, arrangements on other layout levels or quantities of conductors in the set of conductors 532 are within the scope of the present disclosure.

The set of vias 522 includes at least one of vias 422a, 422b, 422c or 522d.

In comparison with integrated circuit 400, via 522d of the set of vias 522 is similar to one or more of vias 422a, 422b or 422c of the set of vias 422, and similar detailed description is omitted for brevity.

Via 522f electrically couples conductor 532f and contact 414c together.

In some embodiments, by including conductor 532f in integrated circuit 500, the read bit line RBL is located on both the front-side 403a of integrated circuit 500 as conductor 430e and the back-side 403b of integrated circuit 500 as conductor 532f, thereby improving the speed of integrated circuit 500 compared to other approaches.

In some embodiments, integrated circuit 500 achieves one or more of the benefits described herein.

In some embodiments, by including conductor 516a in the first region 511 of integrated circuit 500, conductor 516a is in direct contact with contact 510d and 512c, and thereby electrically couples contact 510d and contact 512c together, thus electrically coupling the drain terminal of NFET transistor N3-2 and the drain terminal of NFET transistor N1-2 with the drain terminal of PFET transistor P1-2 and the drain terminal of PFET transistor P3-2 together, thereby resulting in additional routing resources of integrated circuit 400 compared to other approaches.

Other configurations, arrangements on other layout levels or quantities of elements in integrated circuit 500 are within the scope of the present disclosure.

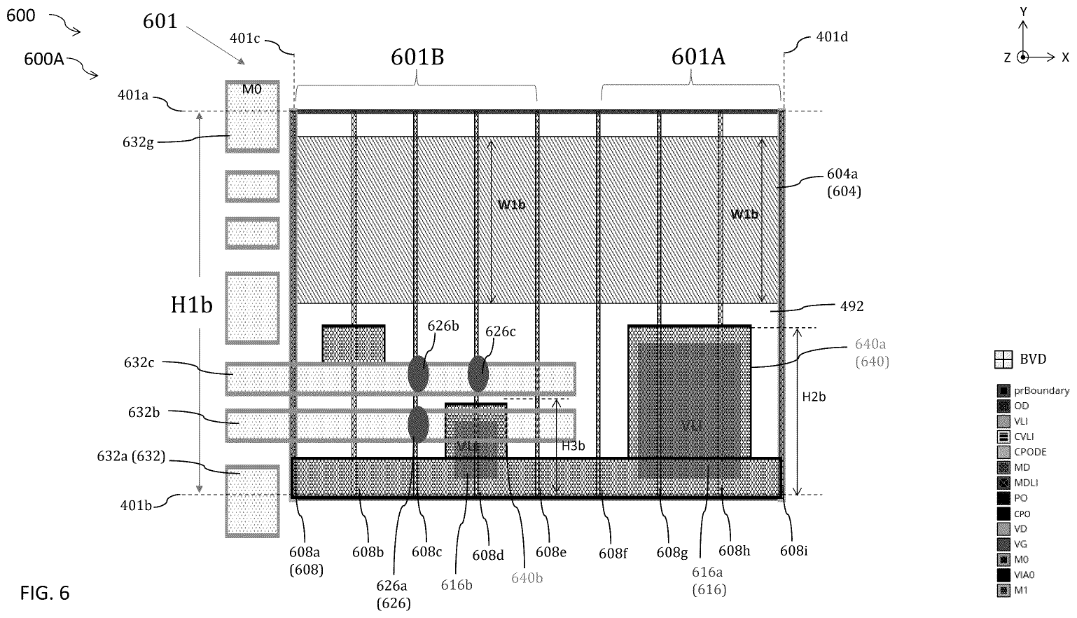

FIG. 6 is a diagram of an integrated circuit 600, in accordance with some embodiments.

Integrated circuit 600 includes one or more features of the OD level, the POLY level, the CPO level, the BMD level, the VLI level, the CVLI level, the BM0 level and the BVG level.

Integrated circuit 600 is manufactured by a corresponding layout design similar to integrated circuit 600. While integrated circuit 600 is described as an integrated circuit, integrated circuit 600 can also be a layout design similar to layout design 300, and similar detailed description will not be described in at least FIG. 6, for brevity.

In some embodiments, integrated circuit 600 is manufactured by a layout design similar to layout design 300, and similar detailed description is therefore omitted.

Integrated circuit 600 is cell 601. Cell 601 is a variation of cell 501 of FIGS. 5A-5H, and similar detailed description is omitted for brevity.

Integrated circuit 600 is a variation of integrated circuit 500 of FIGS. 5A-5H, and similar detailed description is omitted for brevity. In some embodiments, integrated circuit 600 is a variation of portion 500B (back-side) of integrated circuit 500 of FIGS. 5A-5H, and similar detailed description is omitted for brevity.

In comparison with integrated circuit 500 of FIGS. 5A-5H, a set of active regions 604 replaces the set of active regions 404 of integrated circuit 500, a set of gates 608 replaces the set of gates 408 of integrated circuit 500, a set of conductors 616 replaces the set of conductors 516 of integrated circuit 500, a set of insulating regions 640 replaces the set of insulating regions 540 of integrated circuit 500, a set of vias 626 replaces the set of vias 424 of integrated circuit 500, a set of conductors 632 replaces the set of conductors 532 of integrated circuit 500, and similar detailed description is omitted for brevity.

Integrated circuit 600 includes at least the set of active regions 604, the set of gates 608, the set of conductors 616, the set of insulating regions 640, the set of vias 626, the set of conductors 632, the substrate 490 and the insulating region 492.

The set of active regions 404 includes active region 604a.

In comparison with integrated circuit 500, active region 604a of the set of active regions 404 is similar to active region 404a of the set of active regions 404, and similar detailed description is omitted for brevity.

In some embodiments, active region 604a has a height W1b in the second direction Y.

In some embodiments, the height W1b of the set of active region 604 is equal to a first range. In some embodiments, the first range ranges from about 0.65 * CH1 to about 1.5 * CH1, where the CH1 is about ½ of the height H1b (e.g., height H1b/2).

Other ranges or values for the first range are within the scope of the present disclosure.

In some embodiments, the height W1b in the second direction Y of active regions 404a and 404b is constant throughout cell 401 of integrated circuit 400 resulting in improved performance compared to other approaches.

Other configurations, arrangements on other layout levels or quantities of structures in the set of active regions 604 are within the scope of the present disclosure.

The set of gates 608 includes at least one of gate 608a, 608b, 608c, 608d, 608e, 608f, 608g, 608h or 608i.

In comparison with integrated circuit 500, gate 608a or 608i of the set of gates 608 is similar to corresponding gate 408a or 408f of the set of gates 408, and similar detailed description is omitted for brevity.

In comparison with integrated circuit 500, gate 608b, 608c, 608d, 608e, 608f, 608g or 608h of the set of gates 608 is similar to corresponding gate 408b, 408c, 408d or 408e of the set of gates 408, and similar detailed description is omitted for brevity.

Other configurations, arrangements on other layout levels or quantities of gates in the set of gates 608 are within the scope of the present disclosure.

The set of insulating regions 640 includes one or more of insulating region 640a or 640b.

In some embodiments, the set of insulating regions 640 replaces a set of removed gate portions in operation 904 of method 900 (FIG. 9). In some embodiments, insulating region 640a of the set of insulating regions 640 replaces a corresponding removed gate portion of the set of removed gate portions.

In some embodiments, one or more insulating regions 640a or 640b is a corresponding removed gate portion (not labelled), and similar detailed description is therefore omitted.

In some embodiments, one or more insulating regions 640a or 640b is a corresponding protrusion extending in the second direction Y. In some embodiments, the insulating region 640a has a height H2b extending in the second direction Y. In some embodiments, the insulating region 640b has a height H3b extending in the second direction Y. In some embodiments, the height H2b is greater than the height H3b. In some embodiments, the height H2b is different than the height H3b. In some embodiments, the height H2b is the same as the height H3b.

In some embodiments, the height H2b is equal to a second range. In some embodiments, the second range ranges from about 0.05 * CH2 to about 1.3 * CH2, where CH2 is about ½ of the height H1b (e.g., height H1b/2).

Other ranges or values for the second range are within the scope of the present disclosure.

In some embodiments, if the height H2b is greater than the second range, then the height H2b may be insufficient to create enough separation between the set of active regions 604 and the set of conductors 616, thereby causing the width W1b of the set of active regions 604 to be reduced thereby causing the performance of integrated circuit 600 to be reduced compared to other approaches.

In some embodiments, if the height H2b is equal to the second range, then the height H2b is sufficient to create enough separation between the set of active regions 604 and the set of conductors 616, thereby causing the performance of integrated circuit 600 to be increased compared to other approaches.

In some embodiments, if the height H2b is less than the second range, then the height H2b is sufficient to create enough separation between the set of active regions 604 and the set of conductors 616, thereby causing the performance of integrated circuit 600 to be increased compared to other approaches.

In some embodiments, the insulating region 640a separates at least one of gate 608g or 608h from a corresponding gate in an adjacent cell along cell boundary 401b.

In some embodiments, the insulating region 640b separates gate 608d from a corresponding gate in an adjacent cell along cell boundary 401b.

In some embodiments, the one or more insulating regions 640a or 640b is configured to electrically isolate the gates that are adjacent to the corresponding one or more insulating regions 640a or 640b.

Other configurations, arrangements on other layout levels or quantities of insulating regions in the set of insulating regions 640 are within the scope of the present disclosure.

The set of conductors 616 includes at least one of conductor 616a or 616b.

In comparison with integrated circuit 500, at least one of conductor 616a or 616b of the set of conductors 616 is similar to conductor 416a of the set of conductors 416, and similar detailed description is omitted for brevity.

In some embodiments, one or more conductor 616a or 616b is a corresponding protrusion extending in the second direction Y. In some embodiments, the conductor 616a has a first height (not labelled) extending in the second direction Y. In some embodiments, the conductor 616a has a second height (not labelled) extending in the second direction Y. In some embodiments, the first height is greater than the second height. In some embodiments, the first height is different than the second height. In some embodiments, the first type is the same as the second height.

In some embodiments, the set of conductors 616 has an L shape. Other shapes for the set of conductors 616 are within the scope of the present disclosure.

Other configurations, arrangements on other layout levels or quantities of conductors in the set of conductors 616 are within the scope of the present disclosure.

The set of conductors 632 includes one or more conductors 632a, 632b, 632c, 632d, 632e, 632f or 632g.

In comparison with integrated circuit 500, one or more conductors 632a, 632b, 632c, 632d, 632e, 632f or 632g of the set of conductors 632 is similar to one or more of conductors 532a or 532b of the set of conductors 532, and similar detailed description is omitted for brevity.

In some embodiments, the set of conductors 632 is routing tracks in other layers. In some embodiments, the set of conductors 632 corresponds to 7 BM0 routing tracks.

Other configurations, arrangements on other layout levels or quantities of conductors in the set of conductors 530 and 632 are within the scope of the present disclosure.

The set of vias 626 includes one or more of vias 626a, 626b or 626c.

In some embodiments, the set of vias 626 is between the set of gates 608 and the set of conductors 632.

Via 626a is between gate 608c and conductor 632b.

Via 626b is between gate 608c and conductor 632c.

Via 626c is between gate 608d and conductor 632c.

The set of vias 626 is configured to electrically couple one or more gates of the set of gates 608 to the set of conductors 632, and vice versa. Via 626a electrically couples gate 608c and conductor 632b together. Via 626b electrically couples gate 608c and conductor 632c together. Via 626c electrically couples gate 608d and conductor 632c together.

The set of vias 626 is positioned at a back-side via over gate (BVG) level of one or more of integrated circuits 600, 700A or 700B. In some embodiments, the BVG level is below the OD level, the POLY level, the MD level, the VLI level, the CVLI level, the BMD level and the M0 level. In some embodiments, the BVG level is above the BM0 level. In some embodiments, the BVG level is between the POLY level and the BM0 level. In some embodiments, the BVG level is between the second layout level and the eighth layout level. Other layout levels are within the scope of the present disclosure.

Other configurations, arrangements on other layout levels or quantities of vias in the set of vias 626 are within the scope of the present disclosure.

In some embodiments, integrated circuit 600 achieves one or more of the benefits described herein.

In some embodiments, portions of one or more gates of the set of gates 608 are removed from a first region 601A or a second region 601B, and the set of insulating regions 640 and the set of conductors 616 are positioned within the first region 601A and the second region 601B.

In some embodiments, at least one of the first region 601A or the second region 601B are positioned along the cell boundary 401b. In some embodiments, by positioning the set of insulating regions 640 and the set of conductors 616 along the cell boundary 401b of integrated circuit 600, an offset distance in the second direction Y between the set of insulating regions 640 and the cell boundary 301a satisfies CPO process limitations without causing additional offset distances thereby resulting in the height H2b in the second direction Y of active region 604a to be constant throughout cell 601 of integrated circuit 600 resulting in improved performance compared to other approaches.

Other configurations, arrangements on other layout levels or quantities of elements in integrated circuit 600 are within the scope of the present disclosure.

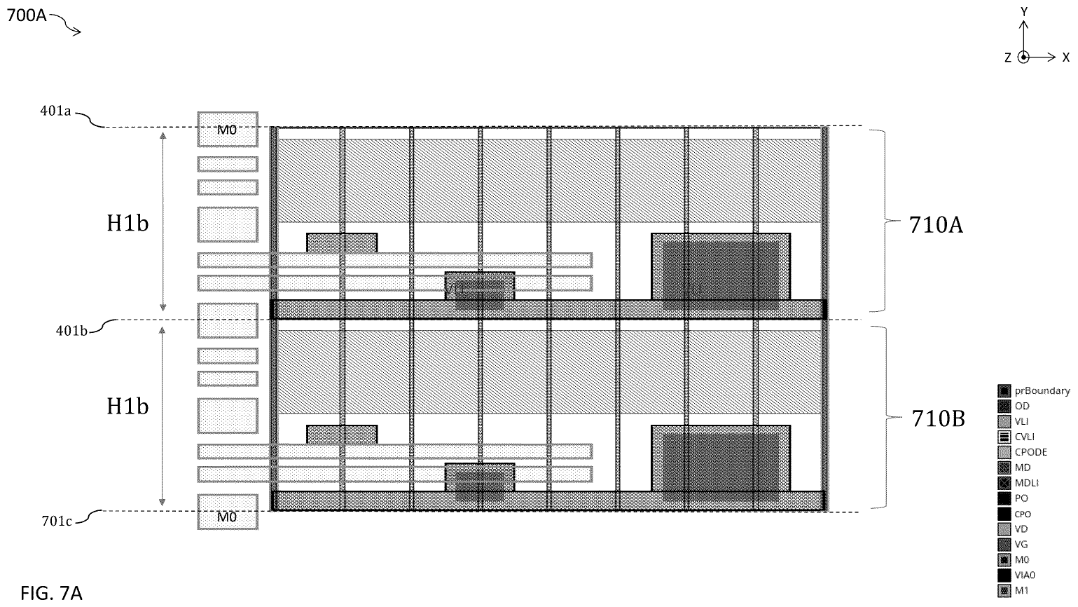

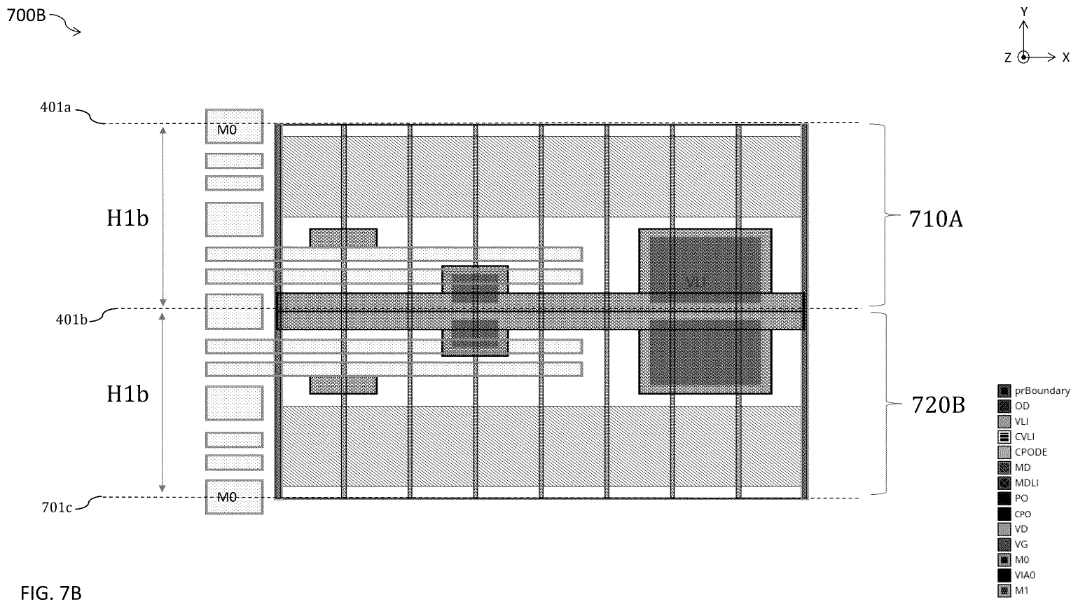

FIGS. 7A-7B are corresponding diagrams of corresponding integrated circuit 700A-700B, in accordance with some embodiments.

Integrated circuits 700A-700B include one or more features of the OD level, the POLY level, the CPO level, the BMD level, the VLI level, the CVLI level, the BM0 level and the BVG level.

Integrated circuit 700A or 700B is manufactured by a corresponding layout design similar to corresponding integrated circuit 700A or 700B. While integrated circuit 700A or 700B is described as an integrated circuit, corresponding integrated circuit 700A or 700B can also be a layout design similar to layout design 300, and similar detailed description will not be described in at least FIGS. 7A-7B, for brevity.

In some embodiments, at least integrated circuit 700A or 700B is manufactured by a layout design similar to layout design 300, and similar detailed description is therefore omitted.

Integrated circuit 700A includes a region 710A and a region 710B.

In some embodiments, region 710A is cell 601 of FIG. 6, and similar detailed description is omitted for brevity.

In some embodiments, region 710B is a variation of region 710A or cell 601 of FIG. 6, and similar detailed description is omitted for brevity. In comparison with region 710A, region 710B is located in an adjacent cell along cell boundary 401b, and similar detailed description is omitted for brevity.

Region 710A is located between cell boundaries 401a and 401b.

Region 710B is located between cell boundaries 401b and 701c.

In some embodiments, cell boundary 701c is similar to cell boundary 401b, and similar detailed description is omitted for brevity.

In some embodiments, regions 710A and 710B are arranged in a stack abutting configuration along cell boundary 401b.

In some embodiments, integrated circuit 700A achieves one or more of the benefits described herein.

Other configurations, arrangements on other layout levels or quantities of elements in integrated circuit 700A are within the scope of the present disclosure.

Integrated circuit 700B is a variation of integrated circuit 700A of FIG. 7A, and similar detailed description is omitted for brevity.

Integrated circuit 700B includes region 710A and a region 720B.

In some embodiments, region 720B is a variation of region 710B of FIG. 7A, and similar detailed description is omitted for brevity. In comparison with region 710B, region 720B replaces region 710B, and similar detailed description is omitted for brevity.

In some embodiments, region 720B is a variation of region 710A or cell 601 of FIG. 6, and similar detailed description is omitted for brevity. In comparison with region 710A, region 720B is a mirror image of region 710A along cell boundary 401b, and similar detailed description is omitted for brevity.

In some embodiments, region 720B is region 710A rotated along cell boundary 401b, and similar detailed description is omitted for brevity.

In some embodiments, regions 710A and 710B are arranged in a flipped stack abutting configuration along cell boundary 401b.

In some embodiments, integrated circuit 700B achieves one or more of the benefits described herein.

Other configurations, arrangements on other layout levels or quantities of elements in integrated circuit 700B are within the scope of the present disclosure.

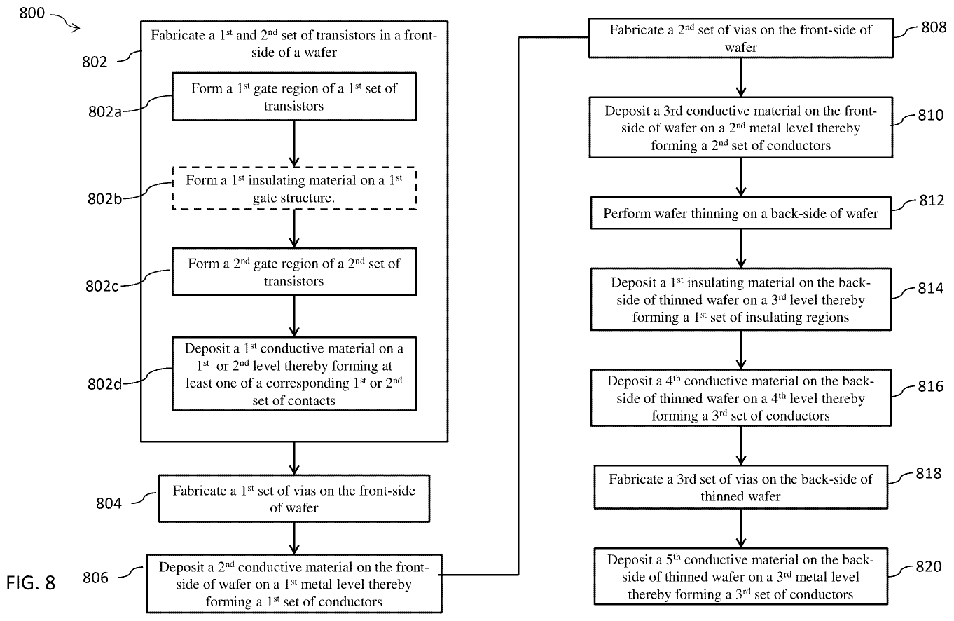

FIG. 8 is a functional flow chart of a method 800 of manufacturing an IC device, in accordance with some embodiments. It is understood that additional operations may be performed before, during, and/or after the method 800 depicted in FIG. 8, and that some other processes may only be briefly described herein.

In some embodiments, other order of operations of method 800-1000 is within the scope of the present disclosure. Method 800-1000 includes exemplary operations, but the operations are not necessarily performed in the order shown. Operations may be added, replaced, changed order, and/or eliminated as appropriate, in accordance with the spirit and scope of disclosed embodiments. In some embodiments, one or more of the operations of at least method 800, 900 or 1000 is not performed.

In some embodiments, method 800 is an embodiment of operation 804 of method 900. In some embodiments, the methods 800-1000 are usable to manufacture or fabricate at least integrated circuit 100, 200, 400, 500, 600, 700A or 700B, or an integrated circuit with similar features as at least layout design 300.

In operation 802 of method 800, a first set of transistors and a second set of transistors are fabricated on a front-side 403a of a semiconductor wafer or substrate. In some embodiments, the first set of transistors or the second set of transistors of method 800 includes one or more transistors in at least the set of active regions 402, 404 or 604. In some embodiments, the first set of transistors or the second set of transistors of method 800 includes one or more transistors described herein.

In some embodiments, operation 802 includes fabricating source and drain regions of the set of transistors in a first well. In some embodiments, the first well comprises p-type dopants. In some embodiments, the p-dopants include boron, aluminum or other suitable p-type dopants. In some embodiments, the first well comprises an epi-layer grown over a substrate. In some embodiments, the epi-layer is doped by adding dopants during the epitaxial process. In some embodiments, the epi-layer is doped by ion implantation after the epi-layer is formed. In some embodiments, the first well is formed by doping the substrate. In some embodiments, the doping is performed by ion implantation. In some embodiments, the first well has a dopant concentration ranging from 1×10¹² atoms/cm³ to 1×10¹⁴ atoms/cm³.

In some embodiments, the first well comprises n-type dopants. In some embodiments, the n-type dopants include phosphorus, arsenic or other suitable n-type dopants. In some embodiments, the n-type dopant concentration ranges from about 1×10¹² atoms/cm³ to about 1×10¹⁴ atoms/cm³.

In some embodiments, the formation of the source/drain features includes, a portion of the substrate is removed to form recesses at an edge of spacers, and a filling process is then performed by filling the recesses in the substrate. In some embodiments, the recesses are etched, for example, a wet etching or a dry etching, after removal of a pad oxide layer or a sacrificial oxide layer. In some embodiments, the etch process is performed to remove a top surface portion of the active region adjacent to an isolation region, such as an STI region. In some embodiments, the filling process is performed by an epitaxy or epitaxial (epi) process. In some embodiments, the recesses are filled using a growth process which is concurrent with an etch process where a growth rate of the growth process is greater than an etch rate of the etch process. In some embodiments, the recesses are filled using a combination of growth process and etch process. For example, a layer of material is grown in the recess and then the grown material is subjected to an etch process to remove a portion of the material. Then a subsequent growth process is performed on the etched material until a desired thickness of the material in the recess is achieved. In some embodiments, the growth process continues until a top surface of the material is above the top surface of the substrate. In some embodiments, the growth process is continued until the top surface of the material is co-planar with the top surface of the substrate. In some embodiments, a portion of the first well is removed by an isotropic or an anisotropic etch process. The etch process selectively etches the first well without etching a gate structure and any spacers. In some embodiments, the etch process is performed using a reactive ion etch (RIE), wet etching, or other suitable techniques. In some embodiments, a semiconductor material is deposited in the recesses to form the source/drain features. In some embodiments, an epi process is performed to deposit the semiconductor material in the recesses. In some embodiments, the epi process includes a selective epitaxy growth (SEG) process, CVD process, molecular beam epitaxy (MBE), other suitable processes, and/or combination thereof. The epi process uses gaseous and/or liquid precursors, which interacts with a composition of substrate. In some embodiments, the source/drain features include epitaxially grown silicon (epi Si), silicon carbide, or silicon germanium. Source/drain features of the IC device associated with the gate structure are in-situ doped or undoped during the epi process in some instances. When source/drain features are undoped during the epi process, source/drain features are doped during a subsequent process in some instances. The subsequent doping process is achieved by an ion implantation, plasma immersion ion implantation, gas and/or solid source diffusion, other suitable processes, and/or combination thereof. In some embodiments, source/drain features are further exposed to annealing processes after forming source/drain features and/or after the subsequent doping process.

In some embodiments, operation 802 further includes operation 802a. In some embodiments, operation 802a includes forming a first gate region of the first set of transistors. In some embodiments, the first gate region of the first set of transistors of method 800 includes the set of gates 408 or 608.

In some embodiments, operation 802 further includes operation 802b. In some embodiments, operation 802b includes forming a first insulating material on a first gate structure of the second set of transistors. In some embodiments, operation 802b includes forming a first insulating material over at least the first gate structure of the first gate regions of the second set of transistors. In some embodiments, the first insulating material includes an insulating region similar to insulating region 492. In some embodiments, operation 802b is not performed.

In some embodiments, operation 802 further includes operation 802c. In some embodiments, operation 802c includes forming a second gate region of the second set of transistors. In some embodiments, the second gate regions of the second set of transistors of method 800 include the set of gates 406. In some embodiments, operations 802a and 802c are performed at the same time.

In some embodiments, the first and second gate region is between the drain region and the source region. In some embodiments, the first and second gate region is over the first well and the substrate. In some embodiments, fabricating the first and second gate regions of operations 802a and 802c include performing one or more deposition processes to form one or more dielectric material layers. In some embodiments, a deposition process includes a chemical vapor deposition (CVD), a plasma enhanced CVD (PECVD), an atomic layer deposition (ALD), or other process suitable for depositing one or more material layers. In some embodiments, fabricating the first and second gate regions includes performing one or more deposition processes to form one or more conductive material layers. In some embodiments, fabricating the first and second gate regions includes forming gate electrodes or dummy gate electrodes. In some embodiments, fabricating the gate regions includes depositing or growing at least one dielectric layer, e.g., gate dielectric. In some embodiments, gate regions are formed using a doped or non-doped polycrystalline silicon (or polysilicon). In some embodiments, the first and second gate regions include a metal, such as Al, Cu, W, Ti, Ta, TiN, TaN, NiSi, CoSi, other suitable conductive materials, or combinations thereof.

In some embodiments, forming the first insulating material on the first gate structure of the first set of transistors of operation 802b includes performing one or more deposition processes to form one or more dielectric material layers and/or insulating material layers. In some embodiments, the one or more deposition processes to form one or more dielectric material layers and/or insulating material layers includes CVD, a PECVD, ALD, or other process suitable for depositing one or more material layers. In some embodiments, forming the first insulating material on the first gate structure of the first set of transistors includes performing one or more deposition processes to form one or more insulating material layers. In some embodiments, the first insulating material is a dielectric material. In some embodiments, the dielectric material includes silicon dioxide, silicon oxy-nitride, or the like.

In some embodiments, operation 802a, 802b and 802c are replaced by forming the first gate regions of the first set of transistors and the second gate regions of the second set of transistors, removing a portion of the first gate regions of the first set of transistors and the second gate regions of the second set of transistors, and forming the first insulating material between the first gate structure of the first set of transistors and the second gate structure of the second set of transistors. In some embodiments, the gate removal process is a POLY cut process that includes one or more etching processes. In some embodiments, the gate removal process includes one or more etching processes suitable to remove a portion of the gate structure. In some embodiments, a mask is used to specify portions of the gate structure that are to be cut or removed. In some embodiments the mask is a hard mask. In some embodiments, the mask is a soft mask. In some embodiments, etching corresponds to plasma etching, reactive ion etching, chemical etching, dry etching, wet etching, other suitable processes, any combination thereof, or the like.

In some embodiments, operation 802 further includes operation 802d. In some embodiments, operation 802d includes depositing a first conductive material on at least one of a first level or a second level thereby forming at least one of a corresponding first set of contacts or a second set of contacts.

In some embodiments, the first set of contacts and the second set of contacts are part of the first set of transistors and the second set of transistors.

In some embodiments, the first set of contacts includes the set of contacts 410 or 510.

In some embodiments, the second set of contacts includes the set of contacts 412 or 512.

In some embodiments, the gate removal process of operations 802a, 802b or 802c also include the formation of the set of gates 406, 408 or 608, and the cut regions are identified by the set of cut feature patterns 340 of FIGS. 3A-3D. In some embodiments, after the gate removal process of operations 802a, 802b or 802c and after operation 802d, method 800 further includes one or more operations to form the set of insulating regions 440, 540 or 640 where the removed portions of the set of gates 406, 408 or 608 are located.

In operation 804 of method 800, a first set of vias are formed on the front-side 403a of the wafer or substrate on a VD level or a VG level (e.g., VD or VG). In some embodiments, the first set of vias of method 800 includes one or more portions of at least the set of vias 420, 424, 520 or 524.

In some embodiments, operation 804 includes forming a first set of self-aligned contacts (SACs) in the insulating layer over the front-side 403a of the wafer. In some embodiments, the first set of vias is electrically coupled to at least the first set of transistors or the second set of transistors.

In operation 806 of method 800, a second conductive material is deposited on the front-side 403a of the substrate on a first metal level thereby forming a first set of conductors on the front-side 403a of the wafer or substrate on the first metal level (e.g., M0).

In some embodiments, operation 806 includes at least depositing a first set of conductive regions over the front-side 403a of the integrated circuit. In some embodiments, the first set of conductors of method 800 includes one or more portions of at least the set of conductors 430 or 530.

In operation 808 of method 800, a second set of vias are formed on the front-side 403a of the wafer or substrate on a V0 level (e.g., V0). In some embodiments, the second set of vias of method 800 includes one or more portions of at least the set of vias 450 or 550.

In some embodiments, operation 808 includes forming a second set of self-aligned contacts (SACs) in the insulating layer over the front-side 403a of the wafer. In some embodiments, the second set of vias is electrically coupled to at least the first set of transistors or the second set of transistors.

In operation 810 of method 800, a third conductive material is deposited on the front-side 403a of the substrate on a second metal level thereby forming a second set of conductors on the front-side 403a of the wafer or substrate on a second metal level (e.g., M1).

In some embodiments, operation 810 includes at least depositing a second set of conductive regions over the front-side 403a of the integrated circuit. In some embodiments, the second set of conductors of method 800 includes one or more portions of at least the set of conductors 460 or 560.

In operation 812 of method 800, thinning is performed on the back-side 403b of the wafer or substrate. In some embodiments, operation 812 includes a thinning process performed on the back-side 403b of the semiconductor wafer or substrate. In some embodiments, the thinning process includes a grinding operation and a polishing operation (such as chemical mechanical polishing (CMP)) or other suitable processes. In some embodiments, after the thinning process, a wet etching operation is performed to remove defects formed on the back-side 403b of the semiconductor wafer or substrate.

In operation 814 of method 800, a first insulating material is deposited on the back-side 403b of the substrate on a third level thereby forming a first set of insulating regions on the back-side 403b of the wafer or substrate on the CVLI level.

In some embodiments, the first set of insulating regions of method 800 includes one or more portions of at least the set of insulating regions 418 or 518.

In operation 816 of method 800, a fourth conductive material is deposited on the back-side 403b of the substrate on a fourth level thereby forming a third set of conductors on the back-side 403b of the wafer or substrate on the VLI level.

In some embodiments, operation 816 includes at least depositing a third set of conductive regions over the back-side 403b of the integrated circuit. In some embodiments, the third set of conductors of method 800 includes one or more portions of at least the set of conductors 416, 516 or 616.

In operation 818 of method 800, a third set of vias are formed on the back-side 403b of the thinned wafer or substrate on a BVD level or a BVG level (e.g., BVD or BVG). In some embodiments, the third set of vias of method 800 includes one or more portions of at least the set of vias 422, 522 or 626.

In some embodiments, operation 818 includes forming a third set of self-aligned contacts (SACs) in the insulating layer over the back-side 403b of the wafer. In some embodiments, the third set of vias is electrically coupled to at least the first set of transistors or the second set of transistors.

In operation 820 of method 800, a fifth conductive material is deposited on the back-side 403b of the substrate on a third metal level thereby forming a fourth set of conductors on the back-side 403b of the wafer or substrate on the third metal level (e.g., BM0).

In some embodiments, operation 820 includes at least depositing a fourth set of conductive regions over the back-side 403b of the integrated circuit. In some embodiments, the fourth set of conductors of method 800 includes one or more portions of at least the set of conductors 432, 532 or 632.

In some embodiments, one or more of operations 802, 804, 806, 808, 810, 814, 816, 818 or 820 of method 800 include using a combination of photolithography and material removal processes to form openings in an insulating layer (not shown) over the substrate. In some embodiments, the photolithography process includes patterning a photoresist, such as a positive photoresist or a negative photoresist. In some embodiments, the photolithography process includes forming a hard mask, an antireflective structure, or another suitable photolithography structure. In some embodiments, the material removal process includes a wet etching process, a dry etching process, an RIE process, laser drilling or another suitable etching process. The openings are then filled with conductive material, e.g., copper, aluminum, titanium, nickel, tungsten, or other suitable conductive material. In some embodiments, the openings are filled using CVD, PVD, sputtering, ALD or other suitable formation process.

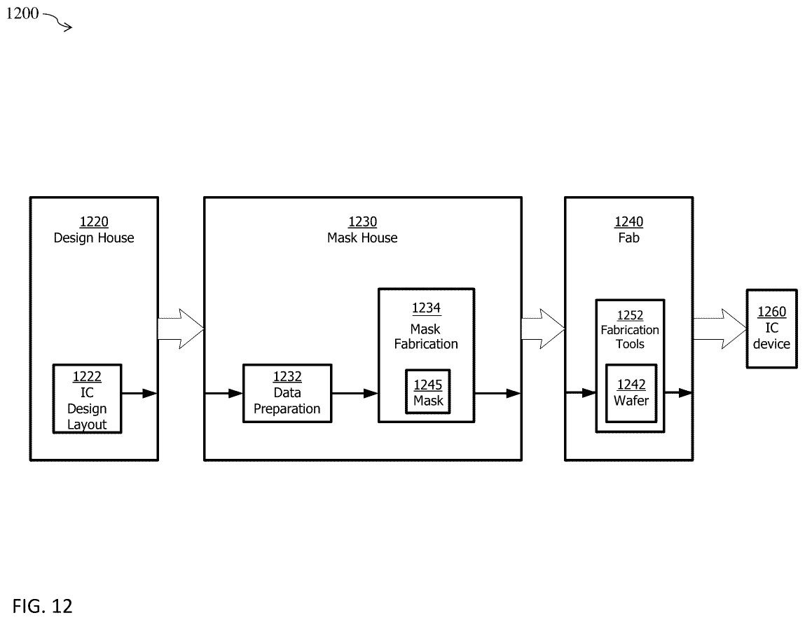

In some embodiments, at least one or more operations of method 800 is performed by system 1200 of FIG. 12. In some embodiments, at least one method(s), such as method 800 discussed above, is performed in whole or in part by at least one manufacturing system, including system 1200. One or more of the operations of method 800 is performed by IC fab 1240 (FIG. 12) to fabricate IC device 1260. In some embodiments, one or more of the operations of method 800 is performed by fabrication tools 1252 to fabricate wafer 1242.

In some embodiments, the conductive material includes copper, aluminum, titanium, nickel, tungsten, or other suitable conductive material. In some embodiments, the openings and trench are filled using CVD, PVD, sputtering, ALD or other suitable formation process. In some embodiments, after conductive material is deposited in one or more of operations 802d, 806, 810, 816 or 820, the conductive material is planarized to provide a level surface for subsequent steps.

In some embodiments, one or more of the operations of method 800, 900 or 1000 is not performed.

One or more of the operations of methods 900-1000 is performed by a processing device configured to execute instructions for manufacturing an integrated circuit, such as at least integrated circuit 100, 200, 400, 500, 600, 700A or 700B. In some embodiments, one or more operations of methods 900-1000 is performed using a same processing device as that used in a different one or more operations of methods 900-1000. In some embodiments, a different processing device is used to perform one or more operations of methods 900-1000 from that used to perform a different one or more operations of methods 900-1000. In some embodiments, other order of operations of method 800, 900 or 1000 is within the scope of the present disclosure. Method 800, 900 or 1000 includes exemplary operations, but the operations are not necessarily performed in the order shown. Operations in method 800, 900 or 1000 may be added, replaced, changed order, and/or eliminated as appropriate, in accordance with the spirit and scope of disclosed embodiments.

FIG. 9 is a flowchart of a method 900 of forming or manufacturing an integrated circuit in accordance with some embodiments. It is understood that additional operations may be performed before, during, and/or after the method 900 depicted in FIG. 9, and that some other operations may only be briefly described herein. In some embodiments, the method 900 is usable to form integrated circuits, such as at least integrated circuit 100, 200, 400, 500, 600, 700A or 700B. In some embodiments, the method 900 is usable to form integrated circuits having similar features and similar structural relationships as one or more of layout design 300.

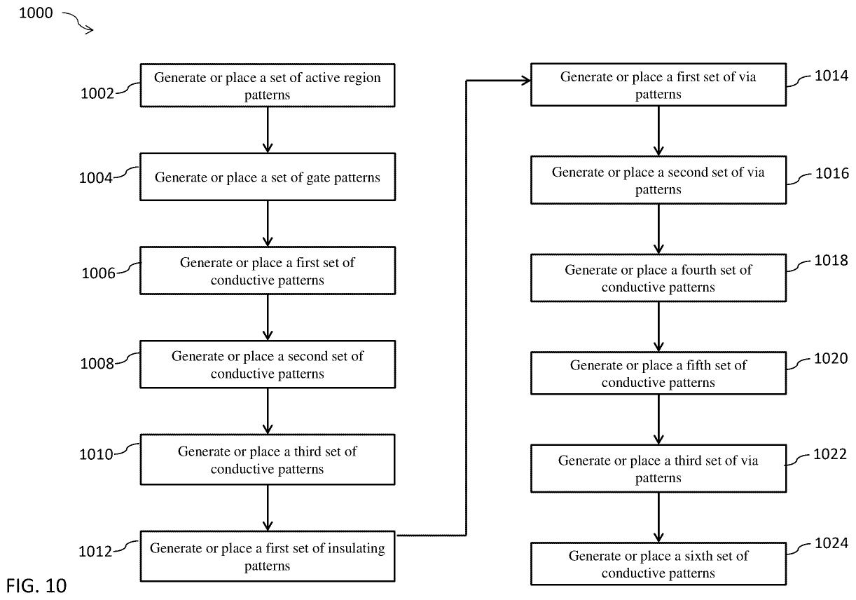

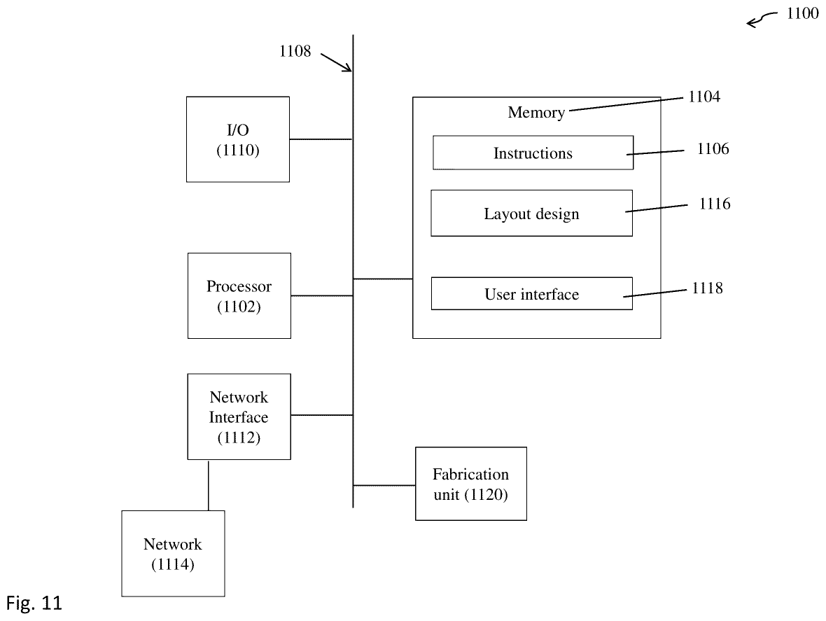

In operation 902 of method 900, a layout design of an integrated circuit is generated. Operation 902 is performed by a processing device (e.g., processor 1102 (FIG. 11)) configured to execute instructions for generating a layout design. In some embodiments, the layout design of method 900 includes one or more patterns of at least layout design 300, or one or more features similar to at least integrated circuit 100, 200, 400, 500, 600, 700A or 700B. In some embodiments, the layout design of the present application is in a graphic database system (GDSII) file format. In some embodiments, operation 902 corresponds to method 1000 of FIG. 10.

In operation 904 of method 900, the integrated circuit is manufactured based on the layout design. In some embodiments, operation 904 of method 900 comprises manufacturing at least one mask based on the layout design, and manufacturing the integrated circuit based on the at least one mask. In some embodiments, operation 904 corresponds to method 800 of FIG. 8.

FIG. 10 is a flowchart of a method 1000 of generating a layout design of an integrated circuit, in accordance with some embodiments. It is understood that additional operations may be performed before, during, and/or after the method 1000 depicted in FIG. 10, and that some other processes may only be briefly described herein. In some embodiments, method 1000 is an embodiment of operation 902 of method 900. In some embodiments, method 1000 is usable to generate one or more layout patterns of at least layout design 300, or one or more features similar to at least integrated circuit 100, 200, 400, 500, 600, 700A or 700B.

In some embodiments, method 1000 is usable to generate one or more layout patterns having structural relationships including alignment, lengths and widths, as well as configurations and layers of at least layout design 300, or one or more features similar to at least integrated circuit 100, 200, 400, 500, 600, 700A or 700B, and similar detailed description will not be described in FIG. 10, for brevity.

In operation 1002 of method 1000, a set of active region patterns is generated or placed on the layout design. In some embodiments, the set of active region patterns of method 1000 includes at least portions of one or more patterns of the set of active region patterns 302 or 304. In some embodiments, the set of active region patterns of method 1000 includes one or more regions similar to the set of active regions 402, 404 or 604. In some embodiments, the set of active region patterns of method 1000 includes one or more patterns or similar patterns in the OD layer.

In operation 1004 of method 1000, a set of gate patterns is generated or placed on the layout design. In some embodiments, the set of gate patterns of method 1000 includes at least portions of one or more patterns of the set of gate patterns 306 or 308 or the set of cut feature patterns 340. In some embodiments, the set of active gate patterns of method 1000 includes one or more regions similar to the set of gates 406, 408 or 608. In some embodiments, the set of gate patterns of method 1000 includes at least portions of one or more patterns of the set of cut feature patterns 340. In some embodiments, the set of gate patterns of method 1000 includes one or more regions similar to the set of insulating regions 440, 540 or 640. In some embodiments, the set of gate patterns of method 1000 includes one or more patterns or similar patterns in the POLY layer.

In operation 1006 of method 1000, a first set of conductive patterns is generated or placed on the layout design. In some embodiments, the first set of conductive patterns of method 1000 includes at least portions of one or more patterns of the set of contact patterns 310. In some embodiments, the first set of conductive patterns of method 1000 includes one or more patterns similar to the set of contacts 410 or 510. In some embodiments, the first set of conductive patterns of method 1000 includes one or more patterns or similar patterns in the MD layer.

In operation 1008 of method 1000, a second set of conductive patterns is generated or placed on the layout design. In some embodiments, the second set of conductive patterns of method 1000 includes at least portions of one or more patterns of the set of contact patterns 312. In some embodiments, the second set of conductive patterns of method 1000 includes one or more patterns similar to the set of contacts 412 or 512. In some embodiments, the second set of conductive patterns of method 1000 includes one or more patterns or similar patterns in the BMD layer.

In operation 1010 of method 1000, a third set of conductive patterns is generated or placed on the layout design. In some embodiments, the third set of conductive patterns of method 1000 includes at least portions of one or more patterns of the set of conductive feature patterns 316. In some embodiments, the third set of conductive patterns of method 1000 includes one or more patterns similar to the set of conductors 416, 516 or 616. In some embodiments, the third set of conductive patterns of method 1000 includes one or more patterns or similar patterns in the VLI layer.

In operation 1012 of method 1000, a first set of insulating feature patterns is generated or placed on the layout design. In some embodiments, the first set of insulating feature patterns of method 1000 includes at least portions of one or more patterns of the set of insulating feature patterns 318. In some embodiments, the first set of insulating feature patterns of method 1000 includes one or more patterns similar to the set of insulating regions 418 or 518. In some embodiments, the fourth set of conductive patterns of method 1000 includes one or more patterns or similar patterns in the CVLI layer.

In operation 1014 of method 1000, a first set of via patterns is generated or placed on the layout design. In some embodiments, the first set of via patterns of method 1000 includes at least portions of one or more patterns of the set of via patterns 320 or 324. In some embodiments, the first set of via patterns of method 1000 includes one or more via patterns similar to at least the set of vias 420, 424, 520 or 524. In some embodiments, the first set of via patterns of method 1000 includes one or more patterns or similar vias in the VG or VD layer.

In operation 1016 of method 1000, a second set of via patterns is generated or placed on the layout design. In some embodiments, the second set of via patterns of method 1000 includes at least portions of one or more patterns of the set of via patterns 322. In some embodiments, the second set of via patterns of method 1000 includes one or more via patterns similar to at least the set of vias 422, 522 or 626. In some embodiments, the second set of via patterns of method 1000 includes one or more patterns or similar vias in the BVG or BVD layer.

In operation 1018 of method 1000, a fourth set of conductive patterns is generated or placed on the layout design. In some embodiments, the fourth set of conductive patterns of method 1000 includes at least portions of one or more patterns of at least the set of conductive feature patterns 330. In some embodiments, the fourth set of conductive patterns of method 1000 includes one or more conductive patterns similar to at least the set of conductors 430 or 530. In some embodiments, the fourth set of conductive patterns of method 1000 includes one or more patterns or similar conductors in the M0 layer.

In operation 1020 of method 1000, a fifth set of conductive patterns is generated or placed on the layout design. In some embodiments, the fifth set of conductive patterns of method 1000 includes at least portions of one or more patterns of at least the set of conductive feature patterns 332. In some embodiments, the fifth set of conductive patterns of method 1000 includes one or more conductive patterns similar to at least the set of conductors 432, 532 or 632. In some embodiments, the fifth set of conductive patterns of method 1000 includes one or more patterns or similar conductors in the BM0 layer.

In operation 1022 of method 1000, a third set of via patterns is generated or placed on the layout design. In some embodiments, the third set of via patterns of method 1000 includes at least portions of one or more patterns of the set of via patterns 350. In some embodiments, the third set of via patterns of method 1000 includes one or more via patterns similar to at least the set of vias 450 or 550. In some embodiments, the third set of via patterns of method 1000 includes one or more patterns or similar vias in the V0 layer.

In operation 1024 of method 1000, a sixth set of conductive patterns is generated or placed on the layout design. In some embodiments, the sixth set of conductive patterns of method 1000 includes at least portions of one or more patterns of at least the set of conductive feature patterns 360. In some embodiments, the sixth set of conductive patterns of method 1000 includes one or more conductive patterns similar to at least the set of conductors 460 or 560. In some embodiments, the sixth set of conductive patterns of method 1000 includes one or more patterns or similar conductors in the M1 layer.

FIG. 11 is a schematic view of a system 1100 for designing an IC layout design and manufacturing an IC circuit in accordance with some embodiments.

In some embodiments, system 1100 generates or places one or more IC layout designs described herein. System 1100 includes a hardware processor 1102 and a non-transitory, computer readable storage medium 1104 (e.g., memory 1104) encoded with, i.e., storing, the computer program code 1106, i.e., a set of executable instructions 1106 (also referred to as “instructions 1106”). Computer readable storage medium 1104 is configured for interfacing with manufacturing machines for producing the integrated circuit. The processor 1102 is electrically coupled to the computer readable storage medium 1104 via a bus 1108. The processor 1102 is also electrically coupled to an I/O interface 1110 by bus 1108. A network interface 1112 is also electrically connected to the processor 1102 via bus 1108. Network interface 1112 is connected to a network 1114, so that processor 1102 and computer readable storage medium 1104 are capable of connecting to external elements via network 1114. The processor 1102 is configured to execute the computer program code 1106 encoded in the computer readable storage medium 1104 in order to cause system 1100 to be usable for performing a portion or all of the operations as described in method 900-1000.

In some embodiments, the processor 1102 is a central processing unit (CPU), a multi-processor, a distributed processing system, an application specific integrated circuit (ASIC), and/or a suitable processing unit.

In some embodiments, the computer readable storage medium 1104 is an electronic, magnetic, optical, electromagnetic, infrared, and/or a semiconductor system (or apparatus or device). For example, the computer readable storage medium 1104 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 1104 includes a compact disk-read only memory (CD-ROM), a compact disk-read/write (CD-R/W), and/or a digital video disc (DVD).

In some embodiments, the storage medium 1104 stores the computer program code 1106 configured to cause system 1100 to perform method 900-1000. In some embodiments, the storage medium 1104 also stores information needed for performing method 900-1000 as well as information generated during performing method 900-1000, such as layout design 1116, user interface 1118 and fabrication unit 1120, and/or a set of executable instructions to perform the operation of method 900-1000. In some embodiments, layout design 1116 comprises one or more of layout patterns of at least layout design 300, or features similar to at least integrated circuit 100, 200, 400, 500, 600, 700A or 700B.

In some embodiments, the storage medium 1104 stores instructions (e.g., computer program code 1106) for interfacing with manufacturing machines. The instructions (e.g., computer program code 1106) enable processor 1102 to generate manufacturing instructions readable by the manufacturing machines to effectively implement method 900-1000 during a manufacturing process.

System 1100 includes I/O interface 1110. I/O interface 1110 is coupled to external circuitry. In some embodiments, I/O interface 1110 includes a keyboard, keypad, mouse, trackball, trackpad, and/or cursor direction keys for communicating information and commands to processor 1102.

System 1100 also includes network interface 1112 coupled to the processor 1102. Network interface 1112 allows system 1100 to communicate with network 1114, to which one or more other computer systems are connected. Network interface 1112 includes wireless network interfaces such as BLUETOOTH, WIFI, WIMAX, GPRS, or WCDMA; or wired network interface such as ETHERNET, USB, or IEEE-2094. In some embodiments, method 900-1000 is implemented in two or more systems 1100, and information such as layout design, and user interface are exchanged between different systems 1100 by network 1114.

System 1100 is configured to receive information related to a layout design through I/O interface 1110 or network interface 1112. The information is transferred to processor 1102 by bus 1108 to determine a layout design for producing at least integrated circuit 100, 200, 400, 500, 600, 700A or 700B. The layout design is then stored in computer readable medium 1104 as layout design 1116. System 1100 is configured to receive information related to a user interface through I/O interface 1110 or network interface 1112. The information is stored in computer readable medium 1104 as user interface 1118. System 1100 is configured to receive information related to a fabrication unit 1120 through I/O interface 1110 or network interface 1112. The information is stored in computer readable medium 1104 as fabrication unit 1120. In some embodiments, the fabrication unit 1120 includes fabrication information utilized by system 1100. In some embodiments, the fabrication unit 1120 corresponds to mask fabrication 1234 of FIG. 12.

In some embodiments, method 900-1000 is implemented as a standalone software application for execution by a processor. In some embodiments, method 900-1000 is implemented as a software application that is a part of an additional software application. In some embodiments, method 900-1000 is implemented as a plug-in to a software application. In some embodiments, method 900-1000 is implemented as a software application that is a portion of an EDA tool. In some embodiments, method 900-1000 is implemented as a software application that is used by an EDA tool. In some embodiments, the EDA tool is used to generate a layout of the integrated circuit device. In some embodiments, the layout is stored on a non-transitory computer readable medium. In some embodiments, the layout is generated using a tool such as VIRTUOSO® available from CADENCE DESIGN SYSTEMS, Inc., or another suitable layout generating tool. In some embodiments, the layout is generated based on a netlist which is created based on the schematic design. In some embodiments, method 900-1000 is implemented by a manufacturing device to manufacture an integrated circuit using a set of masks manufactured based on one or more layout designs generated by system 1100. In some embodiments, system 1100 is a manufacturing device configured to manufacture an integrated circuit using a set of masks manufactured based on one or more layout designs of the present disclosure. In some embodiments, system 1100 of FIG. 11 generates layout designs of an integrated circuit that are smaller than other approaches. In some embodiments, system 1100 of FIG. 11 generates layout designs of integrated circuit structure that occupy less area and provide better routing resources than other approaches.

FIG. 12 is a block diagram of an integrated circuit (IC) manufacturing system 1200, and an IC manufacturing flow associated therewith, in accordance with at least one embodiment of the present disclosure. In some embodiments, based on a layout diagram, at least one of (A) one or more semiconductor masks or (B) at least one component in a layer of a semiconductor integrated circuit is fabricated using manufacturing system 1200.

In FIG. 12, IC manufacturing system 1200 (hereinafter “system 1200”) includes entities, such as a design house 1220, a mask house 1230, and an IC manufacturer/fabricator (“fab”) 1240, that interact with one another in the design, development, and manufacturing cycles and/or services related to manufacturing an IC device 1260. The entities in system 1200 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, one or more of design house 1220, mask house 1230, and IC fab 1240 is owned by a single larger company. In some embodiments, one or more of design house 1220, mask house 1230, and IC fab 1240 coexist in a common facility and use common resources.

Design house (or design team) 1220 generates an IC design layout 1222. IC design layout 1222 includes various geometrical patterns designed for an IC device 1260. The geometrical patterns correspond to patterns of metal, oxide, or semiconductor layers that make up the various components of IC device 1260 to be fabricated. The various layers combine to form various IC features. For example, a portion of IC design layout 1222 includes various IC features, such as an active region, gate electrode, source electrode and drain electrode, metal lines or vias of an interlayer interconnection, and openings for bonding pads, to be formed in a semiconductor substrate (such as a silicon wafer) and various material layers disposed on the semiconductor substrate. Design house 1220 implements a proper design procedure to form IC design layout 1222. The design procedure includes one or more of logic design, physical design or place and route. IC design layout 1222 is presented in one or more data files having information of the geometrical patterns. For example, IC design layout 1222 can be expressed in a GDSII file format or DFII file format.

Mask house 1230 includes data preparation 1232 and mask fabrication 1234. Mask house 1230 uses IC design layout 1222 to manufacture one or more masks 1245 to be used for fabricating the various layers of IC device 1260 according to IC design layout 1222. Mask house 1230 performs mask data preparation 1232, where IC design layout 1222 is translated into a representative data file (RDF). Mask data preparation 1232 provides the RDF to mask fabrication 1234. Mask fabrication 1234 includes a mask writer. A mask writer converts the RDF to an image on a substrate, such as a mask (reticle) 1245 or a semiconductor wafer 1242. The IC design layout 1222 is manipulated by mask data preparation 1232 to comply with particular characteristics of the mask writer and/or requirements of IC fab 1240. In FIG. 12, mask data preparation 1232 and mask fabrication 1234 are illustrated as separate elements. In some embodiments, mask data preparation 1232 and mask fabrication 1234 can be collectively referred to as mask data preparation.

In some embodiments, mask data preparation 1232 includes optical proximity correction (OPC) which uses lithography enhancement techniques to compensate for image errors, such as those that can arise from diffraction, interference, other process effects and the like. OPC adjusts IC design layout 1222. In some embodiments, mask data preparation 1232 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1232 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 1234, which may undo part of the modifications performed by OPC in order to meet mask creation rules.

In some embodiments, mask data preparation 1232 includes lithography process checking (LPC) that simulates processing that will be implemented by IC fab 1240 to fabricate IC device 1260. LPC simulates this processing based on IC design layout 1222 to create a simulated manufactured device, such as IC device 1260. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout 1222.

It should be understood that the above description of mask data preparation 1232 has been simplified for the purposes of clarity. In some embodiments, data preparation 1232 includes additional features such as a logic operation (LOP) to modify the IC design layout according to manufacturing rules. Additionally, the processes applied to IC design layout 1222 during data preparation 1232 may be executed in a variety of different orders.

After mask data preparation 1232 and during mask fabrication 1234, a mask 1245 or a group of masks 1245 are fabricated based on the modified IC design layout 1222. In some embodiments, mask fabrication 1234 includes performing one or more lithographic exposures based on IC design layout 1222. In some embodiments, an electron-beam (e-beam) or a mechanism of multiple e-beams is used to form a pattern on a mask (photomask or reticle) 1245 based on the modified IC design layout 1222. The mask 1245 can be formed in various technologies. In some embodiments, the mask 1245 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary version of mask 1245 includes a transparent substrate (e.g., fused quartz) and an opaque material (e.g., chromium) coated in the opaque regions of the binary mask. In another example, the mask 1245 is formed using a phase shift technology. In the phase shift mask (PSM) version of mask 1245, various features in the pattern formed on the mask are configured to have proper phase difference to enhance the resolution and imaging quality. In various examples, the phase shift mask can be attenuated PSM or alternating PSM. The mask(s) generated by mask fabrication 1234 is used in a variety of processes. For example, such a mask(s) is used in an ion implantation process to form various doped regions in the semiconductor wafer, in an etching process to form various etching regions in the semiconductor wafer, and/or in other suitable processes.

IC fab 1240 is an IC fabrication entity that includes one or more manufacturing facilities for the fabrication of a variety of different IC products. In some embodiments, IC Fab 1240 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry entity.

IC fab 1240 includes wafer fabrication tools 1252 (hereinafter “fabrication tools 1252”) configured to execute various manufacturing operations on semiconductor wafer 1242 such that IC device 1260 is fabricated in accordance with the mask(s), e.g., mask 1245. In various embodiments, fabrication tools 1252 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1240 uses mask(s) 1245 fabricated by mask house 1230 to fabricate IC device 1260. Thus, IC fab 1240 at least indirectly uses IC design layout 1222 to fabricate IC device 1260. In some embodiments, a semiconductor wafer 1242 is fabricated by IC fab 1240 using mask(s) 1245 to form IC device 1260. In some embodiments, the IC fabrication includes performing one or more lithographic exposures based at least indirectly on IC design 1222. Semiconductor wafer 1242 includes a silicon substrate or other proper substrate having material layers formed thereon. Semiconductor wafer 1242 further includes one or more of various doped regions, dielectric features, multilevel interconnects, and the like (formed at subsequent manufacturing steps).

System 1200 is shown as having design house 1220, mask house 1230 or IC fab 1240 as separate components or entities. However, it is understood that one or more of design house 1220, mask house 1230 or IC fab 1240 are part of the same component or entity.

One aspect of this description relates to an integrated circuit. In some embodiments, the integrated circuit includes a first active region extending in a first direction, being on a first level above a front-side of a substrate, and the first active region corresponding to a first set of transistors of a first dopant type. In some embodiments, the integrated circuit further includes a second active region extending in the first direction, being on a second level below the first level, and the second active region corresponding to a second set of transistors of a second dopant type different from the first dopant type. In some embodiments, the integrated circuit further includes a first contact extending in a second direction different from the first direction, and the first contact being on a third level different from the first level and the second level, and overlapping the first active region. In some embodiments, the integrated circuit further includes a second contact extending in the second direction, being on a fourth level below the third level, and overlapping the second active region, and the second contact being separated from the first contact in the first direction and a third direction different from the first direction and the second direction. In some embodiments, the integrated circuit further includes a first conductor extending in the first direction, being on the third level and the fourth level, and being coupled to the first contact and the second contact. In some embodiments, the integrated circuit further includes a first insulating region extending in the first direction, being on the fourth level, and being within a recess of the first conductor. In some embodiments, a top surface of the first conductor is flush with a top surface of the first insulating region. In some embodiments, the first contact is electrically coupled to the second contact by the first conductor.

Another aspect of this description relates to an integrated circuit. In some embodiments, the integrated circuit includes a first active region extending in a first direction, being on a first level above a front-side of a substrate. In some embodiments, the first active region includes a first drain region of a first transistor of a first type and a second drain region of a second transistor of the first type. In some embodiments, the integrated circuit further includes a second active region extending in the first direction, being on a second level below the first level. In some embodiments, the second active region includes a third drain region of a third transistor of a second type and a fourth drain region of a fourth transistor of the second type, the second type being different from the first type. In some embodiments, the integrated circuit further includes a first contact extending in a second direction different from the first direction, and the first contact being on a third level different from the first level and the second level, overlapping the first active region, and being coupled to the first drain region and the second drain region. In some embodiments, the integrated circuit further includes a second contact extending in the second direction, being on a fourth level different from the first level, the second level and the third level, and overlapping the second active region, and the second contact being separated from the first contact in the first direction and a third direction different from the first direction and the second direction, and being coupled to the third drain region and the fourth drain region. In some embodiments, the integrated circuit further includes a first conductor extending in the first direction, being on the third level and the fourth level, and being coupled to the first contact and the second contact.

Still another aspect of this description relates to a method of fabricating an integrated circuit. In some embodiments, the method includes fabricating a first set of transistors and a second set of transistors in a front-side of a substrate, the first set of transistors being stacked above the second set of transistors. In some embodiments, fabricating the first set of transistors and the second set of transistors includes fabricating a first set of contacts on a first level of the front-side of the substrate and a second set of contacts on a second level, the first set of contacts being electrically coupled to the first set of transistors, and the second set of contacts being electrically coupled to the second set of transistors. In some embodiments, the method further includes fabricating a first set of vias on the front-side of the substrate, the first set of vias being electrically coupled to at least the first set of transistors. In some embodiments, the method further includes depositing a first conductive material on the front-side of the substrate on a first metal level thereby forming a first set of conductors, the first set of conductors being electrically coupled to the first set of transistors by the first set of vias. In some embodiments, the method further includes performing thinning on a back-side of the substrate opposite from the front-side. In some embodiments, the method further includes fabricating a second set of conductors in the back-side of the thinned substrate, the second set of conductors being in the first level and the second level, being embedded in the thinned substrate, and a first conductor of the second set of conductors is electrically coupled to a first contact of the first set of contacts and a first contact of the second set of contacts.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a first active region extending in a first direction, being on a first level above a front-side of a substrate, and the first active region corresponding to a first set of transistors of a first dopant type;
a second active region extending in the first direction, being on a second level below the first level, and the second active region corresponding to a second set of transistors of a second dopant type different from the first dopant type;
a first contact extending in a second direction different from the first direction, and the first contact being on a third level different from the first level and the second level, and overlapping the first active region;
a second contact extending in the second direction, being on a fourth level below the third level, and overlapping the second active region, and the second contact being separated from the first contact in the first direction and a third direction different from the first direction and the second direction;
a first conductor extending in the first direction, being on the third level and the fourth level, and being coupled to the first contact and the second contact and
a first insulating region extending in the first direction, being on the fourth level, and being within a recess of the first conductor, wherein a top surface of the first conductor is flush with a top surface of the first insulating region, and the first contact is electrically coupled to the second contact by the first conductor.

2. The integrated circuit of claim 1, wherein the first conductor comprises:
a first conductive portion extending in the first direction, being on the third level and the fourth level, and being coupled to the first contact; and
a second conductive portion extending in the first direction, being on the fourth level, and being coupled to the second contact.

3. The integrated circuit of claim 2, wherein the first contact protrudes into the first conductive portion; and
the second contact protrudes into the second conductive portion.

4. The integrated circuit of claim 2, wherein the first conductor has an L-shape.

5. The integrated circuit of claim 1, further comprising:
a first gate extending in the second direction, and the first gate being on the third level, and overlapping the first active region; and
a second gate extending in the second direction, and the second gate being on the fourth level, overlapping the second active region, and being coupled to the first gate.

6. The integrated circuit of claim 5, wherein the first gate and the second gate are between the first contact and the second contact.

7. The integrated circuit of claim 6, further comprising:
a second insulating region extending in the first direction, and being on the third level and the fourth level, and the second insulating region corresponding to a removed portion of the first gate and a removed portion of the second gate.

8. The integrated circuit of claim 1, wherein the first set of transistors and the second set of transistors are part of an AND OR INVERT logic circuit or an OR AND INVERT logic circuit.

9. The integrated circuit of claim 1, wherein
the first active region comprises:
a first drain region of a first transistor of the first set of transistors; and
a second drain region of a second transistor of the first set of transistors;
the second active region comprises:
a third drain region of a third transistor of the second set of transistors; and
a fourth drain region of a fourth transistor of the second set of transistors;
the first contact is coupled to the first drain region and the second drain region;
the second contact is coupled to the third drain region and the fourth drain region; and
the first conductor electrically couples the first drain region and the second drain region to the third drain region and the fourth drain region.

10. An integrated circuit, comprising:
a first active region extending in a first direction, being on a first level above a front-side of a substrate, and the first active region comprises:
a first drain region of a first transistor of a first type and a second drain region of a second transistor of the first type;
a second active region extending in the first direction, being on a second level below the first level, and the second active region comprises:
a third drain region of a third transistor of a second type and a fourth drain region of a fourth transistor of the second type, the second type being different from the first type;
a first contact extending in a second direction different from the first direction, and the first contact being on a third level different from the first level and the second level, overlapping the first active region, and being coupled to the first drain region and the second drain region;
a second contact extending in the second direction, being on a fourth level different from the first level, the second level and the third level, and overlapping the second active region, and the second contact being separated from the first contact in the first direction and a third direction different from the first direction and the second direction, and being coupled to the third drain region and the fourth drain region; and
a first conductor extending in the first direction, being on the third level and the fourth level, and being coupled to the first contact and the second contact.

11. The integrated circuit of claim 10, wherein
the first active region further comprises:
a first source region of the first transistor and a fifth drain region of a fifth transistor of the first type;
a second source region of the fifth transistor of the first type;
a third source region of the second transistor and a sixth drain region of a sixth transistor of the first type; and
a fourth source region of the sixth transistor of the first type;
the second active region further comprises:
a fifth source region of the fourth transistor of the second type;
a sixth source region of the third transistor and a seventh drain region of a seventh transistor of the second type;
a seventh source region of the seventh transistor of the second type and an eighth source region of an eighth transistor of the second type; and
an eighth drain region of the eighth transistor of the second type.

12. The integrated circuit of claim 11, further comprising:
a third contact extending in the second direction, being on the third level, overlapping the first active region, and being coupled to the fourth source region of the sixth transistor;
a fourth contact extending in the second direction, being on the third level, overlapping the first active region, and being coupled to the third source region of the second transistor and the sixth drain region of the sixth transistor;
a fifth contact extending in the second direction, being on the third level, overlapping the first active region, and being coupled to the first source region of the first transistor and the fifth drain region of the fifth transistor; and
a sixth contact extending in the second direction, being on the third level, overlapping the first active region, and being coupled to the second source region of the fifth transistor of the first type.

13. The integrated circuit of claim 12, further comprising:
a seventh contact extending in the second direction, being on the fourth level, overlapping the second active region, being separated from the third contact in the third direction, and being coupled to the eighth drain region of the eighth transistor;
an eighth contact extending in the second direction, being on the fourth level, overlapping the second active region, being separated from the fourth contact in the third direction, and being coupled to the seventh source region of the seventh transistor of the second type and the eighth source region of the eighth transistor;
a ninth contact extending in the second direction, being on the fourth level, overlapping the second active region, being separated from the first contact in the third direction, and being coupled to the sixth source region of the third transistor and the seventh drain region of the seventh transistor; and
a tenth contact extending in the second direction, being on the fourth level, overlapping the second active region, being separated from the sixth contact in the third direction, and being coupled to the fifth source region of the fourth transistor.

14. The integrated circuit of claim 13, further comprising:
a first gate extending in the second direction, being on the third level, overlapping the first active region, and being between the third contact and the fourth contact;
a second gate extending in the second direction, being on the third level, overlapping the first active region, and being between the fourth contact and the first contact;
a third gate extending in the second direction, being on the third level, overlapping the first active region, and being between the first contact and the fifth contact; and
a fourth gate extending in the second direction, being on the third level, overlapping the first active region, and being between the fifth contact and the sixth contact.

15. The integrated circuit of claim 14, further comprising:
a second conductor extending in the first direction, being on a fifth level different from the first level, the second level, the third level and the fourth level, and overlapping at least the third contact and the sixth contact;
a third conductor extending in the first direction, being on the fifth level, and overlapping the first contact;
a fourth conductor extending in the first direction, being on the fifth level, and overlapping the first gate;
a fifth conductor extending in the first direction, being on the fifth level, and overlapping the second gate;
a sixth conductor extending in the first direction, being on the fifth level, and overlapping the third gate; and
a seventh conductor extending in the first direction, being on the fifth level, and overlapping the fourth gate.

16. The integrated circuit of claim 15, further comprising:
a first via electrically coupling the second conductor and the third contact together, the first via being between the second conductor and the third contact;
a second via electrically coupling the second conductor and the sixth contact together, the second via being between the second conductor and the sixth contact;
a third via electrically coupling the third conductor and the first contact together, the third via being between the third conductor and the first contact;
a fourth via electrically coupling the fourth conductor and the first gate together, the fourth via being between the fourth conductor and the first gate;
a fifth via electrically coupling the fifth conductor and the second gate together, the fifth via being between the fifth conductor and the second gate;
a sixth via electrically coupling the sixth conductor and the third gate together, the sixth via being between the sixth conductor and the third gate;
a seventh via electrically coupling the seventh conductor and the fourth gate together, the seventh via being between the seventh conductor and the fourth gate;

17. The integrated circuit of claim 16, further comprising:
an eighth conductor extending in the second direction, being on a sixth level different from the first level, the second level, the third level, the fourth level and the fifth level, and overlapping at least the second conductor;
a ninth conductor extending in the second direction, being on the sixth level, and overlapping at least the fifth conductor;
a tenth conductor extending in the second direction, being on the sixth level, and overlapping at least the third conductor;
an eleventh conductor extending in the second direction, being on the sixth level, and overlapping at least the sixth conductor; and
a twelfth conductor extending in the second direction, being on the sixth level, and overlapping at least the seventh conductor.

18. The integrated circuit of claim 17, further comprising:
an eighth via electrically coupling the eighth conductor and the second conductor together, the eighth via being between the eighth conductor and the second conductor;
a ninth via electrically coupling the ninth conductor and the fifth conductor together, the eighth via being between the ninth conductor and the fifth conductor;
a tenth via electrically coupling the tenth conductor and the third conductor together, the eighth via being between the tenth conductor and the third conductor;
an eleventh via electrically coupling the eleventh conductor and the sixth conductor together, the eleventh via being between the eleventh conductor and the sixth conductor; and
a twelfth via electrically coupling the twelfth conductor and the seventh conductor together, the twelfth via being between the twelfth conductor and the seventh conductor.

19. The integrated circuit of claim 15, further comprising:
an eighth conductor extending in the first direction, being on a sixth level different from the first level, the second level, the third level, the fourth level and the fifth level, and being overlapped by at least the eighth contact and the second contact;
a ninth conductor extending in the first direction, being on the sixth level, and being overlapped by at least the seventh contact, the ninth contact and the tenth contact;
a tenth conductor extending in the first direction, being on the sixth level, and being overlapped by at least the eighth contact;
a first via electrically coupling the ninth conductor and the seventh contact together, the first via being between the ninth conductor and the seventh contact;
a second via electrically coupling the ninth conductor and the ninth contact together, the second via being between the ninth conductor and the ninth contact;
a third via electrically coupling the ninth conductor and the tenth contact together, the second via being between the ninth conductor and the tenth contact;
a fourth via electrically coupling the eighth conductor and the eighth contact together, the fourth via being between the eighth conductor and the eighth contact; and
a fifth via electrically coupling the tenth conductor and the eighth contact together, the fifth via being between the tenth conductor and the eighth contact.

20. A method of fabricating an integrated circuit, the method comprising:
fabricating a first set of transistors and a second set of transistors in a front-side of a substrate, the first set of transistors being stacked above the second set of transistors, wherein fabricating the first set of transistors and the second set of transistors comprises:
fabricating a first set of contacts on a first level of the front-side of the substrate and a second set of contacts on a second level, the first set of contacts being electrically coupled to the first set of transistors, and the second set of contacts being electrically coupled to the second set of transistors;
fabricating a first set of vias on the front-side of the substrate, the first set of vias being electrically coupled to at least the first set of transistors;
depositing a first conductive material on the front-side of the substrate on a first metal level thereby forming a first set of conductors, the first set of conductors being electrically coupled to the first set of transistors by the first set of vias;
performing thinning on a back-side of the substrate opposite from the front-side; and
fabricating a second set of conductors in the back-side of the thinned substrate, the second set of conductors being in the first level and the second level, being embedded in the thinned substrate, and a first conductor of the second set of conductors is electrically coupled to a first contact of the first set of contacts and a first contact of the second set of contacts.
